(19) United States
(12) Patent Application Publication
(10) Pub. No.: US 2025/0089390 A1
(43) Pub. Date: Mar. 13, 2025

(54) IMAGE SENSOR AND MANUFATURING METHOD THEREOF

(71) Applicant: Samsung Electronics Co., Ltd., Suwon-si (KR)

(72) Inventors: Sangin Bae, Suwon-si (KR); HYEYEON PARK, Suwon-si (KR); HYUNSEOK SONG, Suwon-si (KR)

(21) Appl. No.: 18/768,346

(22) Filed: Jul. 10, 2024

(30) Foreign Application Priority Data
Sep. 13, 2023 (KR) 10-2023-0121993

(51) Int. Cl. H01L 27/146; G02B 5/20

(52) U.S. Cl. CPC H10F 39/8053; H10F 39/024; H10F 39/182; H10F 39/8063; G02B 5/201

(57) ABSTRACT

An image sensor including a first substrate including first and second surfaces facing each other and a plurality of photoelectric conversion regions, a plurality of color filters positioned on the second surface of the substrate, the plurality of color filters including a first color filter, a second color filter, and a third color filter; and a microlens layer including a plurality of microlenses and positioned to overlap each of the color filters. An upper surface of at least one of the first color filter, the second color filter, or the third color filter has a concave curved surface, and curvature of the upper surface of the third color filter is different from curvature of the upper surface of the second color filter or curvature of the upper surface of the first color filter.

### CROSS-REFERENCE TO RELATED APPLICATION

This application claims priority under 35 U.S.C. § 119 to and the benefit of Korean Patent Application No. 10-2023-0121993, filed in the Korean Intellectual Property Office on Sep. 13, 2023, the entire content of which is incorporated herein by reference.

### BACKGROUND

### 1. Field

The present disclosure relates to an image sensor and a manufacturing method for the image sensor.

### 2. Description of the Related Art

An image sensor is a semiconductor device that converts optical images into electrical signals. The image sensor may be classified into a charge coupled device (CCD) type and a complementary metal oxide semiconductor (CMOS) type, and the CMOS type image sensor is abbreviated as a CMOS image sensor (CIS). The CIS includes a plurality of pixels arranged two-dimensionally, and each of the pixels includes a photodiode (PD). The photodiode plays a role of converting incident light into an electrical signal.

A pixel may be divided into a positive electrode region that accepts light and a negative electrode region that does not accept light. A microlens serves to focus incoming light into the positive electrode region. This structure increases pixel sensitivity and reduces a pixel noise caused by a structure of a target object to be photographed.

Meanwhile, when using a microlens, an angle of incident light may be required to be within a predetermined angle (chief ray angle (CRA)) for light to reach the positive electrode region. If the angle of incoming light deviates from the CRA, shading may occur in a pixel. In addition, wavelengths of red (R), green (G), and blue (B) light are different, so after red, green, and blue light passes through microlenses, focal points at which the light gathers are different. In addition, a channel difference problem may occur in which light passing through the microlens according to a refraction angle passes not into an intended pixel, but into another adjacent pixel.

### SUMMARY OF THE DISCLOSURE

The present disclosure attempts to provide an image sensor that optimizes an optical path for each pixel and reduces a channel difference.

An embodiment of the present disclosure provides an image sensor including: a substrate including first and second surfaces facing each other and a plurality of photoelectric conversion regions; a plurality of color filters positioned on the second surface of the substrate, the plurality of color filters including a first color filter, a second color filter, and a third color filter; and a microlens layer including a plurality of microlenses and positioned to overlap each of the color filters, wherein an upper surface of at least one of the first color filter, the second color filter, or the third color filter has a concave curved surface, and wherein a curvature of the upper surface of the third color filter is different from curvature of the upper surface of the second color filter or curvature of the upper surface of the first color filter.

Another embodiment of the present disclosure provides an image sensor including: a substrate including first and second surfaces facing each other and a plurality of photoelectric conversion regions; a plurality of color filters positioned on the second surface of the substrate, the plurality of color filters including a red color filter, a green color filter, and a blue color filter; a microlens layer including a plurality of microlenses and positioned to overlap each of the color filters, wherein an upper surface of at least one of the red color filter, the green color filter, or the blue color filter includes a concave portion, and wherein a ratio of a depth of a most concave portion of the blue color filter to a width of the blue color filter is different from a ratio of a depth of a most concave portion of the red color filter to a width of the red color filter or a ratio of a depth of a most concave portion of the green color filter to a width of the green color filter.

Another embodiment of the present disclosure provides an image sensor including: a substrate including first and second surfaces facing each other and a plurality of photoelectric conversion regions; a plurality of color filters positioned on the second surface of the substrate, the plurality of color filters including a first color filter, a second color filter, and a third color filter; and a microlens layer including a plurality of microlenses and positioned to overlap each of the color filters, wherein the first substrate includes a central region and an outer region positioned to surround the central region, wherein an upper surface of the third color filter has a concave curved surface, and wherein a curvature of the upper surface of the third color filter positioned in the outer region is greater than the curvature of the upper surface of the third color filter positioned in the central region.

According to the embodiments, an image sensor is provided in which the optical path for each pixel is optimized and channel differences are reduced by forming a concave shape of the color filter.

### BRIEF DESCRIPTION OF THE DRAWINGS

FIG. 1 illustrates an example block diagram of an image sensor according to an embodiment.

FIG. 2 illustrates a circuit diagram of one pixel included in an image sensor according to an embodiment of the present disclosure.

FIG. 3 illustrates a top plan view showing an image sensor according to an embodiment of the present disclosure.

FIG. 4 illustrates a cross-sectional view taken along a line A-A of FIG. 3.

FIG. 5 illustrates an enlarged view of a portion indicated by “B” in FIG. 4.

FIG. 6 illustrates a separate view of a portion indicated by “C” in FIG. 5.

FIG. 7 illustrates a focus of light that is incident on an image sensor having a flat upper surface.

FIG. 8 illustrates incidence and a focus of light in a blue pixel of FIG. 6.

FIG. 9 illustrates an optical path between a third color filter and an interface of a microlens.

FIG. 10 illustrates a region corresponding to that of FIG. 5 for another embodiment.

FIG. 11 illustrates a region corresponding to that of FIG. 5 for another embodiment.

FIG. 12 illustrates a region corresponding to that of FIG. 5 for another embodiment.

FIG. 13 briefly illustrates a pixel array region.

FIG. 14 illustrates an area corresponding to that of FIG. 5 for a pixel positioned in an outer area.

FIG. 15 illustrates a focus of a pixel positioned in an outer area.

FIG. 16 illustrates a focus of a pixel positioned in an outer area of an image sensor according to an embodiment.

FIG. 17 illustrates an optical path between a third color filter and an interface of a microlens.

FIG. 18 illustrates a cross-section corresponding to that of FIG. 14 for another embodiment.

FIG. 19 illustrates a cross-section corresponding to that of FIG. 14 for another embodiment.

FIG. 20 illustrates a cross-section corresponding to that of FIG. 14 for another embodiment.

FIG. 21 illustrates a configuration in which an edge portion of a color filter blocks a path of incident light.

FIG. 22 illustrates a cross-section corresponding to that of FIG. 20 for another embodiment.

FIG. 23 illustrates a cross-section corresponding to that of FIG. 20 for another embodiment.

FIG. 24 illustrates a top plan view describing a structure in which one microlens is formed every 2*2 pixels according to an embodiment.

FIG. 25 illustrates a top plan view describing a structure in which one microlens is formed every 3*3 pixels according to an embodiment.

FIG. 26 illustrates a top plan view describing a structure in which one microlens is formed every 4*4 pixels according to an embodiment.

FIG. 27 illustrates a manufacturing method for a color filter according to an embodiment.

FIG. 28 to FIG. 30 illustrate a manufacturing method for a color filter according to another embodiment.

FIG. 31 to FIG. 36 illustrate a manufacturing method for a color filter according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

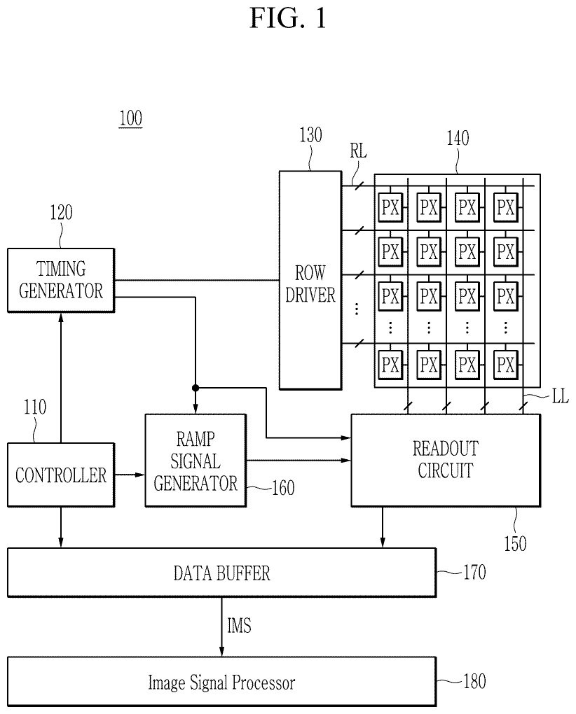

FIG. 1 illustrates an example block diagram of an image sensor according to an embodiment.

Referring to FIG. 1, an image sensor 100 according to an embodiment may include a controller 110, a timing generator 120, a row driver 130, a pixel array 140, a readout circuit 150, a ramp signal generator 160, a data buffer 170, and an image signal processor 180. In an embodiment, the image signal processor 180 may be positioned external to the image sensor 100.

The image sensor 100 may generate an image signal by converting light received from an outside into an electrical signal. An image signal IMS may be supplied to the image signal processor 180.

The image sensor 100 may be mounted on an electronic device having an image or light sensing function. For example, the image sensor 100 may be mounted on an electronic device such as a camera, a smartphone, a wearable device, an Internet of things (IoT) devices, a home appliance, a tablet personal computer (PC), a personal digital assistant (PDA), a portable multimedia player (PMP), a navigation device, a drone, an advanced driver assistance system (ADAS), etc. Alternatively, the image sensor 100 may be mounted on an electronic device provided as a part of a vehicle, a furniture, a manufacturing facility, a door, or various measuring devices.

The controller 110 may generally control each of the components 120, 130, 150, 160, and 170 included in the image sensor 100. The controller 110 may control an operation timing of each of the components 120, 130, 150, 160, and 170 using control signals. In an embodiment, the controller 110 may receive a mode signal indicating an imaging mode from an application processor, and may generally control the image sensor 100 based on the received mode signal. For example, the application processor may determine an imaging mode of the image sensor 100 according to various scenarios such as illumination of an imaging environment, resolution setting of a user, and a sensed or learned state, and may provide a determined result to the controller 110 as a mode signal. The controller 110 may control a plurality of pixels of the pixel array 140 to output pixel signals according to the imaging mode, the pixel array 140 may output a pixel signal for each of the pixels or a pixel signal for some of the pixels, and the readout circuit 150 may sample and process pixel signals received from the pixel array 140. The timing generator 120 may generate a signal that serves as a reference for operation timings of components of the image sensor 100. The timing generator 120 may control timings of the row driver 130, the readout circuit 150, and the ramp signal generator 160. The timing generator 120 may provide a control signal that controls the timings of the low driver 130, the readout circuit 150, and the ramp signal generator 160.

The pixel array 140 may include a plurality of pixels PX, and a plurality of row lines RL and a plurality of column lines LL respectively connected to the pixels PX. In an embodiment, each of the pixels PX may include at least one photoelectric conversion element. The photoelectric conversion element may detect incident light, and may convert the incident light into an electrical signal according to an amount of light, i.e., a plurality of analog pixel signals. The photoelectric conversion element may include a photodiode, a pinned diode, or the like. Additionally, the photoelectric conversion element may be a single-photon avalanche diode (SPAD) applied to a 3D sensor pixel. A level of an analog pixel signal outputted from the photoelectric conversion element may be proportional to an amount of charge outputted from the photoelectric conversion element. That is, the level of the analog pixel signal output from the photoelectric conversion element may be determined according to an amount of light received into the pixel array 140.

The row lines RL may extend in a first direction, and may be connected to the pixels PX positioned along the first direction. For example, a control signal outputted from the row driver 130 to the row line RL may be transferred to gates of transistors of a plurality of pixels PX connected to the row line RL. The columns line LL may extend in a second direction crossing the first direction, and may be connected to the pixels PX positioned along the second direction. A plurality of pixel signals outputted from the pixels PX may be transferred to the readout circuit 150 through the column lines LL.

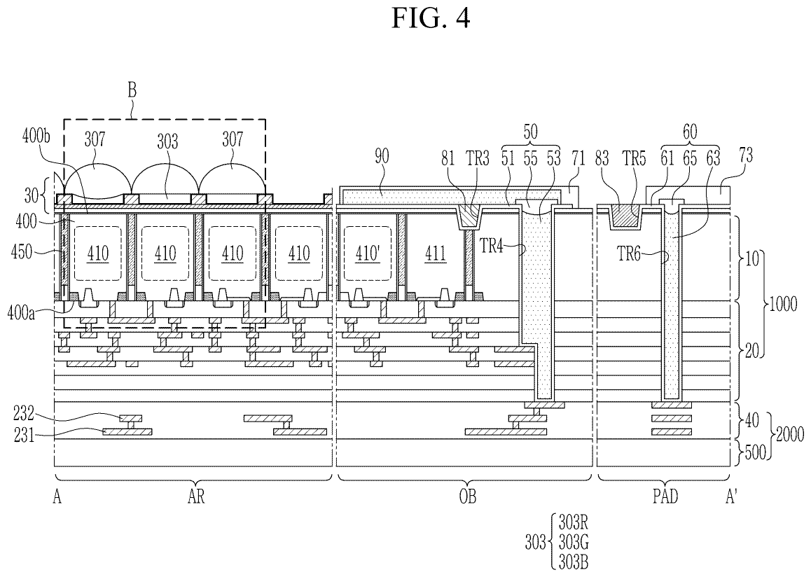

A color filter layer and a microlens layer may be positioned on the pixel array 140. The microlens layer includes a plurality of microlenses, and each of the microlenses may be positioned at an upper portion of the at least one corresponding pixel PX. The color filter layer includes color filters such as red, green, and blue filters, and may additionally include a white filter. For one pixel PX, a color filter of one color may be positioned between the pixel PX and the corresponding microlens. Specific structures of the color filter layer and the microlens layer will be described later in the drawings following FIG. 4.

The row driver 130 may generate a control signal for driving the pixel array 140 in response to a control signal of the timing generator 120, and control signals may be supplied to the pixels PX of the pixel array 140 through the row lines RL. In an embodiment, the row driver 130 may control the pixels PX to sense light incident in a row line unit. The row line unit may include at least one row line RL. For example, the row driver 130 may provide a transfer signal TS, a reset signal RS, a selection signal SEL, etc. to the pixel array 140, as will be described later.

In response to the control signal from the timing generator 120, the readout circuit 150 may convert pixel signals (or electrical signals) from the pixels PX connected to the row line RL selected from among the pixels PX into pixel values representing an amount of light. The readout circuit 150 may convert the pixel signal outputted through the corresponding column line LL into a pixel value. For example, the readout circuit 150 may convert the pixel signal into the pixel value by comparing a ramp signal and the pixel signal. A pixel value may be image data having multiple bits. Specifically, the readout circuit 150 may include a selector, a plurality of comparators, a plurality of counter circuits, and the like.

The ramp signal generator 160 may generate a reference signal to transmit it to the readout circuit 150.

The ramp signal generator 160 may include a current source, a resistor, and a capacitor. The ramp signal generator 160 may generate a plurality of ramp signals that fall or rise with a slope determined according to a current magnitude of a variable current source or a resistance value of a variable resistor by adjusting a ramp voltage, which is a voltage applied to ramp resistance, adjusting the current magnitude of the variable current source or the resistance value of the variable resistor.

The data buffer 170 may store pixel values of the pixels PX connected to the selected column line LL transferred from the readout circuit 150, and may output the stored pixel values in response to an enable signal from the controller 110.

The image signal processor 180 may perform image signal processing on the image signal received from the data buffer 170. For example, the image signal processor 180 may receive a plurality of image signals from the data buffer 170, and may synthesize the received image signals to generate one image.

In an embodiment, the pixels may be grouped in the form of M*N (M and N is an integer of 2 or more) to form one unit pixel group. The M*N form may be a form in which M items are arranged in an arrangement direction of the column lines LL and N items are arranged in an arrangement direction of the row lines RL. For example, one unit pixel group may include a plurality of pixels arranged in a 2*2 format, and one unit pixel group may output one analog pixel signal. The following embodiment is not limited to one pixel, but may also be applied to a group of unit pixels.

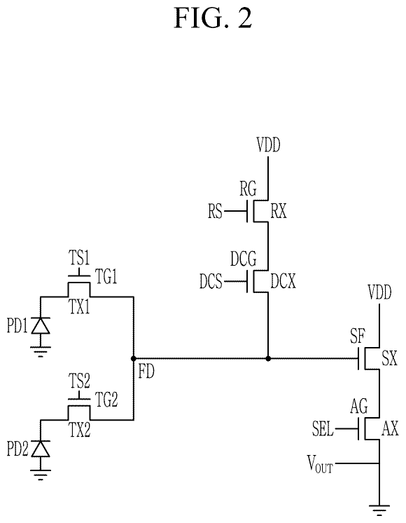

FIG. 2 illustrates a circuit diagram of one pixel included in an image sensor according to an embodiment of the present disclosure.

Referring to FIG. 2, one pixel may include a plurality of photoelectric conversion elements PD1 and PD2. Each of the photoelectric conversion elements PD1 and PD2 may perform photoelectric conversion. As illustrated in FIG. 2, the photoelectric conversion elements PD1 and PD2 may be connected to one floating diffusion region FD. FIG. 2 illustrates a configuration in which two photoelectric conversion elements are connected to one floating diffusion region FD, but this is only an example, and a number of photoelectric conversion elements connected to one floating diffusion region FD may vary according to the embodiment.

Hereinafter, a description will focus on a first photoelectric conversion element PD1, but the following description equally applies to the other photoelectric conversion element PD2.

The first photoelectric conversion element PD1 may generate and accumulate charge according to an amount of light received. The first photoelectric conversion element PD1 may include an anode connected to ground and a cathode connected to a first end of a first transmission transistor TX1. A first transmission signal TS1 may be supplied to a gate TG1 of the first transmission transistor TX1, and the first end of the first transmission transistor TX1 may be connected to the floating diffusion region FD. If the first transmission transistor TX1 is turned on by the first transmission signal TS1, charges charged in the first photoelectric conversion element PD1 may be transferred to the floating diffusion region FD. The floating diffusion region FD may maintain the charges transferred from the photoelectric conversion element PD1.

Each of a plurality of transmission transistors TX1 and TX2 is connected between one of the photoelectric conversion elements PD1 and PD2 and the floating diffusion region FD, and may respectively include gate electrodes TG1 and TG2 that respectively receive a plurality of transmission signals TS1 and TS2. For example, the first transmission transistor TX1 may be connected between the first photoelectric conversion element PD1 and the floating diffusion area FD, and may include the gate electrode TG1 that receives the first transmission signal TS1. A number of the transmission transistors TX1 and TX2 may be equal to that of the photoelectric conversion elements PD1 and PD2.

The reset transistor RX may be connected between the power supply voltage VDD and the floating diffusion area FD, and may include the gate electrode RG that receives a reset signal RS.

The reset transistor RX may periodically reset the charges accumulated in the floating diffusion region FD. A drain electrode of the reset transistor RX may be connected to a source electrode of a dual conversion transistor DCX, and the source electrode may be connected to a power supply voltage VDD. If the reset transistor RX is turned on, the power supply voltage VDD connected to the source electrode of the reset transistor RX may be applied to the floating diffusion region FD. Accordingly, if the reset transistor RX is turned on, the charges accumulated in the floating diffusion region FD may be discharged to reset the floating diffusion region FD.

The dual conversion transistor DCX may be positioned between the reset transistor RX and the floating diffusion region FD, and may include a gate electrode DCG that receives a dual conversion signal DCS. The dual conversion transistor DCX may reset the floating diffusion region FD together with the reset transistor RX. According to another embodiment, the dual conversion transistor DCX may be omitted.

A drain electrode of the dual conversion transistor DCX may be connected to the floating diffusion region FD, and the source electrode of the dual conversion transistor DCX may be connected to the drain electrode of the reset transistor RX. If the reset transistor RX and the dual conversion transistor DCX are turned on, the power supply voltage VDD connected to the source electrode of the reset transistor RX may be applied to the floating diffusion region FD through the dual conversion transistor DCX. Accordingly, the charges accumulated in the floating diffusion region FD may be discharged to reset the floating diffusion region FD.

An amplification transistor SX may output a pixel signal according to a voltage of the floating diffusion region FD. A gate SF of the amplifying transistor SX may be connected to the floating diffusion region FD, a power supply voltage VDD may be supplied to a source electrode of the amplifying transistor SX, and a drain electrode of the amplifying transistor SX may be connected to a first end of a selection transistor AX. The amplifying transistor SX may constitute a source follower circuit, and may output a voltage of a level corresponding to the charges accumulated in the floating diffusion region FD as a pixel signal.

If the selection transistor AX is turned on by the selection signal SEL, the pixel signal from the amplification transistor SX may be transferred to the readout circuit. The selection signal SEL may be applied to the gate electrode AG of the selection transistor AX, and the drain electrode of the selection transistor AX may be connected to an output wire Vout that outputs a plurality of pixel signals.

An operation of the image sensor will be described with reference to FIG. 2 as follows. First, with light blocked, the power supply voltage VDD is applied to the drain electrode of the reset transistor RX and the drain electrode of the amplification transistor SX. Subsequently, the reset transistor RX and the dual conversion transistor DCX are turned on to discharge the remaining charges in the floating diffusion region FD. Thereafter, if the reset transistor RX is turned off and external light is incident on the photoelectric conversion elements PD1 and PD2, electron-hole pairs are generated in each of the photoelectric conversion elements PD1 and PD2. Holes move to p-type impurity regions of the photoelectric conversion elements PD1 and PD2, and electrons move to n-type impurity regions to be accumulated. If the transmission transistors TX1 and TX2 are turned on, charges such as electrons and holes are transferred to the floating diffusion region FD to be accumulated. A gate bias of the amplification transistor SX changes in proportion to the accumulated charges, which causes a change in the source potential of the amplification transistor SX. In this case, if the selection transistor AX is turned on, a signal (proportional to the charges) is read through the output wire Vout.

A wire may be electrically connected to at least one of the gate electrodes TG1 and TG2 of transmission transistors TX1 and TX2, the gate electrodes SF of the amplification transistor SX, the gate electrode DCG of the dual conversion transistor DCX, the gate electrode RG of the reset transistor RX, or the gate electrode AG of the select transistor AX. The wire may include a power supply voltage transmission wire that applies the power supply voltage VDD to the source electrode of the reset transistor RX or the source electrode of the amplification transistor SX. The wire may include an output wire Vout connected to the selection transistor AX.

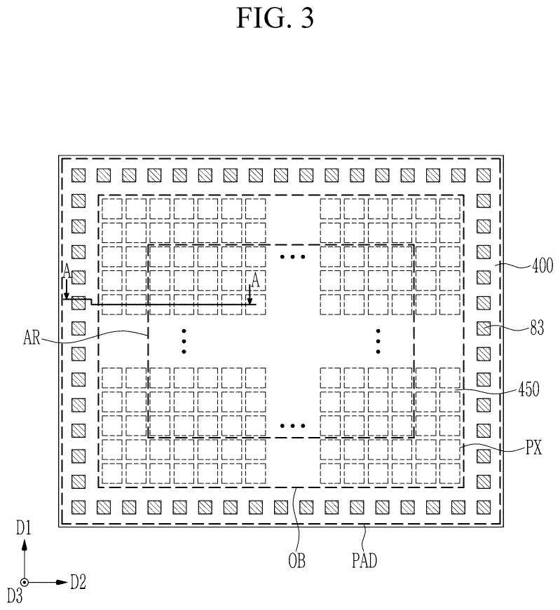

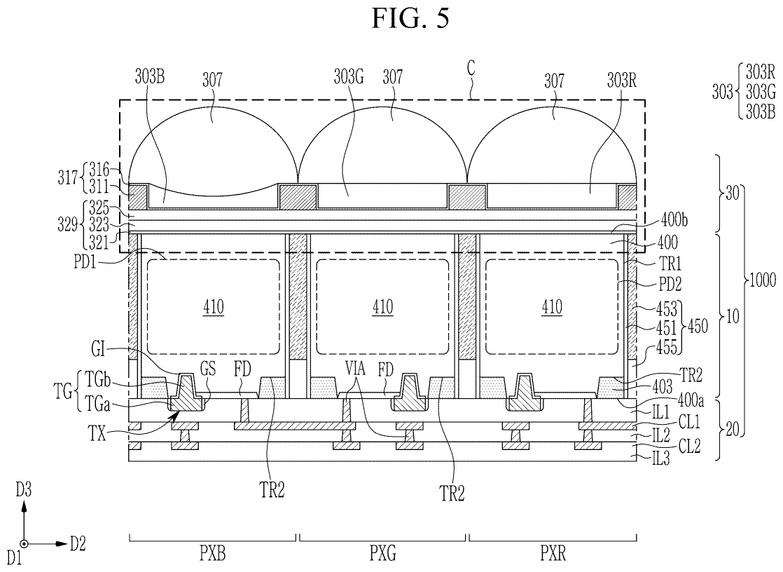

FIG. 3 illustrates a top plan view showing an image sensor according to an embodiment of the present disclosure. FIG. 4 illustrates a cross-sectional view taken along a line A-A of FIG. 3. FIG. 5 illustrates an enlarged view of a portion indicated by “B” in FIG. 4.

However, plan and cross sections of FIG. 3 to FIG. 5 are example cross sections for convenience of description, but the present disclosure is not limited thereto. For example, pixels illustrated in FIG. 4 and FIG. 5 are illustrated as being positioned at an edge of a pixel array region AR, but the present disclosure not limited thereto, and they may be pixels positioned in a center of the pixel array region AR.

Referring to FIG. 3 to FIG. 5, the image sensor according to the present embodiment may include a sensor chip 1000 and a logic chip 2000. The sensor chip 1000 may include a photoelectric conversion layer 10, a first wiring region 20, and a light transmission layer 30. The photoelectric conversion layer 10 may include a first substrate 400, a pixel separation pattern 450, and a photoelectric conversion region 410 positioned within the first substrate 400. Light incident from an outside may be converted into an electrical signal in the photoelectric conversion region 410.

Referring to FIG. 3, the first substrate 400 may include a pixel array region AR, an optical black region OB, and a pad region PAD in a plan view. The pixel array region AR may be positioned in a central region of the first substrate 400 in a plan view. The pixel array region AR may include a plurality of pixels PX. The pixels PX may output a photoelectric signal from incident light. The pixels PX may be positioned along rows parallel to a first direction D1 and columns parallel to a second direction D2.

The pad region PAD may be positioned at an edge of the first substrate 400, and may surround the pixel array area (AR). A plurality of pad terminals 83 may be positioned in the pad region PAD. The pad terminals 83 may output electrical signals generated from the pixels PX to the outside. Alternatively, an external electrical signal or a voltage may be transferred to the pixels PX through the pad terminals 83. The pad region PAD may be positioned at an edge of the first substrate 400, and thus the pad terminals 83 may be easily connected to the outside.

The optical black region OB may be positioned between the pixel array region AR and the pad region PAD of the first substrate 400. The optical black region OB may surround the pixel array region AR. The optical black region OB may include a plurality of dummy regions 411. A signal generated in the dummy region 411 may be used as information to remove a process noise later.

Referring to FIG. 4 and FIG. 5, the image sensor may include a photoelectric conversion layer 10, a gate electrode TG of a transmission transistor, a first wiring region 20, and a light transmission layer 30. The photoelectric conversion layer 10 may include a first substrate 400 and a pixel separation pattern 450. Although not illustrated in FIG. 4 and FIG. 5, the gate electrode AG of the selection transistor AX may be positioned on a same layer as the gate electrode RG of the reset transistor RX, the gate electrode DCG of the dual conversion transistor DCX, the gate electrode SF of the amplification transistor SX, and the gate electrode TG of the transmission transistor. However, this is an example, and according to an embodiment, the gate electrode RG of the reset transistor RX, the gate electrode DCG of the dual conversion transistor DCX, the gate electrode SF of the amplification transistor SX, and the gate electrode AG of the selection transistor AX may be electrically connected to each other while positioned on a different substrate from the gate electrode TG of the transmission transistor.

Hereinafter, the sensor chip 1000 in the pixel array region AR will be described with primary reference to FIG. 5. The sensor chip 1000 includes a first substrate 400. The first substrate 400 may include a first surface 400a and a second surface 400b facing each other. Light may be incident on the second surface 400b of the first substrate 400. The first wiring region 20 may be positioned on the first surface 400a of the first substrate 400, and the light transmission layer 30 may be positioned on the second surface 400b of the first substrate 400. The first substrate 400 may be a semiconductor substrate or a silicon on insulator (SOI) substrate. For example, the semiconductor substrate may include a silicon substrate, a germanium substrate, or a silicon-germanium substrate. The first substrate 400 may include impurities of a first conductivity type. For example, the impurities of the first conductivity type may be p-type impurities such as aluminum (Al), boron (B), indium (In) and/or gallium (Ga).

Referring to FIG. 3, the first substrate 400 may include a plurality of pixels PX defined by the pixel separation pattern 450. The pixels PX may be arranged in a matrix form along the first and second directions D1 and D2 that intersect each other. The first substrate 400 may include a photoelectric conversion region 410.

The photoelectric conversion region 410 may perform the same function and role as those of the photoelectric conversion elements PD1 and PD2 illustrated in FIG. 2.

The photoelectric conversion region 410 may be a region doped with impurities of a second conductivity type in the first substrate 400. The impurities of the second conductivity type may have a conductivity type opposite to that of the impurities of the first conductivity type. The impurities of the second conductivity type may include n-type impurities such as phosphorus, arsenic, bismuth, and/or antimony. For example, each photoelectric conversion region 410 may include a first region adjacent to the first surface 400a and a second region adjacent to the second surface 400b. There may be a difference in impurity concentration between the first region and the second region of the photoelectric conversion region 410. Accordingly, the photoelectric conversion region 410 may have a potential slope between the first surface 400a and the second surface 400b of the first substrate 400. As another example, the photoelectric conversion region 410 may not have a potential slope between the first surface 400a and the second surface 400b of the first substrate 400.

The first substrate 400 and the photoelectric conversion region 410 may constitute a photodiode. That is, the photodiode may be formed by a pn junction between the first substrate 400 of the first conductivity type and the photoelectric conversion region 410 of the second conductivity type. The photoelectric conversion region 410 constituting the photodiode may generate and accumulate charges (i.e., photo-charges) in proportion to intensity of incident light.

Referring to FIG. 4, the pixel separation pattern 450 may be positioned on the first substrate 400. The pixel separation pattern 450 may have a grid structure and may partition each pixel in a plan view.

Referring to FIG. 5, the pixel separation pattern 450 may be positioned within a first trench TR1. The first trench TR1 may be recessed from the first surface 400a of the first substrate 400. The pixel separation pattern 450 may extend from the first surface 400a of the first substrate 400 toward the second surface 400b. The pixel separation pattern 450 may be a deep trench isolation (DTI) film. The pixel separation pattern 450 may extend through the first substrate 400. A vertical height of the pixel separation pattern 450 may be substantially the same as a vertical thickness of the first substrate 400. A width of the pixel separation pattern 450 may gradually decrease from the first surface 400a to the second surface 400b of the first substrate 400.

The pixel separation pattern 450 may include a first separation pattern 451, a second separation pattern 453, and a capping pattern 455. The first separation pattern 451 may be positioned along a sidewall of the first trench TR1. The first separation pattern 451 may include, e.g., a silicon-based insulating material (e.g., a silicon nitride, a silicon oxide, or a silicon oxynitride) or a high dielectric material (e.g., a hafnium oxide or an aluminum oxide). As another example, the first separation pattern 451 may include a plurality of layers, and the layers may include different materials. The first separation pattern 451 may have a lower refractive index than that of the first substrate 400. Accordingly, crosstalk between pixels PX positioned on the first substrate 400 may be prevented or reduced.

The second separation pattern 453 may be positioned within the first separation pattern 451. For example, a sidewall of the second separation pattern 453 may be surrounded by the first separation pattern 451. The first separation pattern 451 may be positioned between the second separation pattern 453 and the first substrate 400. The second separation pattern 453 may be separated from the first substrate 400 by the first separation pattern 451. Accordingly, if the image sensor operates, the second separation pattern 453 may be electrically separated from the first substrate 400. The second separation pattern 453 may include a crystalline semiconductor material, e.g., polycrystalline silicon. As an example, the second separation pattern 453 may further include a dopant, and the dopant may include impurities of the first conductivity type or impurities of the second conductivity type.

For example, the second separation pattern 453 may include doped polycrystalline silicon. Alternatively, the second separation pattern 453 may include an undoped crystalline semiconductor material. For example, the second separation pattern 453 may include undoped polycrystalline silicon. The term “undoped” may indicate that no intentional doping process has been performed. The dopant may include an n-type dopant and a p-type dopant.

The capping pattern 455 may be positioned on a lower surface of the second separation pattern 453. The capping pattern 455 may be positioned adjacent to the first surface 400a of the first substrate 400. A lower surface of the capping pattern 455 may be coplanar with the first surface 400a of the first substrate 400. An upper surface of the capping pattern 455 may be substantially positioned at the same vertical position as the lower surface of the second separation pattern 453. The capping pattern 455 may include a non-conductive material. As an example, the capping pattern 455 may include, e.g., a silicon-based insulating material (e.g., a silicon nitride, a silicon oxide, or a silicon oxynitride) or a high dielectric material (e.g., a hafnium oxide or an aluminum oxide). Accordingly, the pixel separation pattern 450 may prevent photo-charges generated by incident light incident on the pixels PX from being incident on another adjacent pixels PX due to random drift. That is, the pixel separation pattern 450 may prevent crosstalk between the pixels PX.

The device separation pattern 403 may be positioned within the first substrate 400. For example, a device separation pattern 403 may be positioned within a second trench TR2. The second trench TR2 may be recessed from the first surface 400a of the first substrate 400. The device separation pattern 403 may be a shallow trench isolation (STI) film. The device separation pattern 403 may define an activation pattern. An upper surface of the device separation pattern 403 may be positioned within the first substrate 400. A width of the device separation pattern 403 may gradually decrease as the device separation pattern 403 extends from the first surface 400a toward the second surface 400b of the first substrate 400. The upper surface of the device separation pattern 403 may be vertically spaced apart from the photoelectric conversion region 410.

Although not illustrated in FIG. 4 and FIG. 5, referring to FIG. 2 as well, the amplification transistor SX and the selection transistor AX may also be positioned on the first side 400a of the first substrate 400. That is, the gate electrode SF of the amplification transistor SX and the gate electrode AG of the selection transistor AX may be positioned on the first surface 400a of the first substrate 400. In addition, the reset transistor RX and the dual conversion transistor DCX may be positioned on the first surface 400a of the first substrate 400. The reset transistor RX may include the reset gate RG, and the dual conversion transistor DCX may include the dual conversion gate DCG.

A gate dielectric film GI may be positioned between each of the transmission gate TG, the selection gate AG, the amplification gate SG, the dual conversion gate DCG, and the reset gate RG and the first substrate 400. A gate spacer GS may be positioned on a sidewall of each of the gate electrodes TG, AG, SG, DCG, and RG. The gate spacer GS may include, e.g., a silicon nitride, a silicon carbonitride, or a silicon oxynitride.

However, in another embodiment, it may further include an opposing substrate (not illustrated) that overlaps the first substrate 400, and one or more of the amplifying transistor SX, the selection transistor AX, the reset transistor RX, and the dual conversion transistor DCX may be positioned on an opposing substrate (not illustrated). In this embodiment, at least one of the amplification transistor SX, the selection transistor AX, the reset transistor RX, and the dual conversion transistor DCX positioned on the second substrate and the transmission transistor TX positioned on the first substrate 400 may be connected by a connection node (not illustrated).

The first wiring region 20 may be positioned on the first surface 400a of the first substrate 400, and may include a plurality of insulating layers IL1, IL2, and IL3, a plurality of wiring layers CL1 and CL2, and the via VIA.

The insulating layer may include a first insulating layer IL1, a second insulating layer IL2, and a third insulating layer IL3.

The first insulating layer IL1 may cover the first surface 400a of the first substrate 400. The first insulating layer IL1 may cover the gate electrode TG. The second insulating layer IL2 may be positioned on the first insulating layer IL1. The third insulating layer IL3 may be positioned on the second insulating layer IL2.

The first to third insulating layers IL1, IL2, and IL3 may each include a non-conductive material. For example, the first to third insulating layers IL1, IL2, and IL3 may each include a silicon-based insulating material such as a silicon oxide, a silicon nitride, or a silicon oxynitride.

The first wiring region 20 may include a first wiring layer CL1 and a second wiring layer CL2. The first wiring layer CL1 may be positioned within the second insulating layer IL2

The second wiring layer CL2 may be positioned within the third insulating layer IL3.

A plurality of vias VIA may be positioned in the first insulating layer IL1, the second insulating layer IL2, and the third insulating layer IL3. The vias VIA may connect the floating diffusion region FD, the first wiring layer CL1, and the second wiring layer CL2 to each other.

The first wiring layer CL1, the second wiring layer CL2, and the vias VIA may each include a metal material. As an example, the first wiring layer CL1, the second wiring layer CL2, and the vias VIA may each include copper (Cu).

The light transmission layer 30 may include an insulating structure 329, color filters 303 (i.e., a color filter array), and a microlens layer that includes a plurality of microlenses 307. The light transmission layer 30 may collect and filter light incident from the outside to provide the light to the photoelectric conversion region 410.

The color filter 303 may be positioned on the second surface 400b of the first substrate 400. The color filters 303 may include a plurality of individual color filters 303, which may each be positioned in one pixel PX. An individual color filter 303 in each pixel PX may include primary color filters. Each of I plurality of individual color filters 303 may include one of a first color filter 303R, a second color filter 303G, and a third color filter 303B having different colors.

In FIG. 5, a red pixel PXR, a green pixel PXG, and a blue pixel PXB are illustrated. The first color filter 303R may be positioned to overlap the photoelectric conversion region 410 of the red pixel PXR, the second color filter 303G may be positioned to overlap the photoelectric conversion region 410 of the green pixel PXG, and the third color filter 303B may be positioned to overlap the photoelectric conversion region 410 of the blue pixel PXB. The first color filter 303R may be a red color filter, the second color filter 303G may be a green color filter, and the third color filter 303B may be a blue color filter.

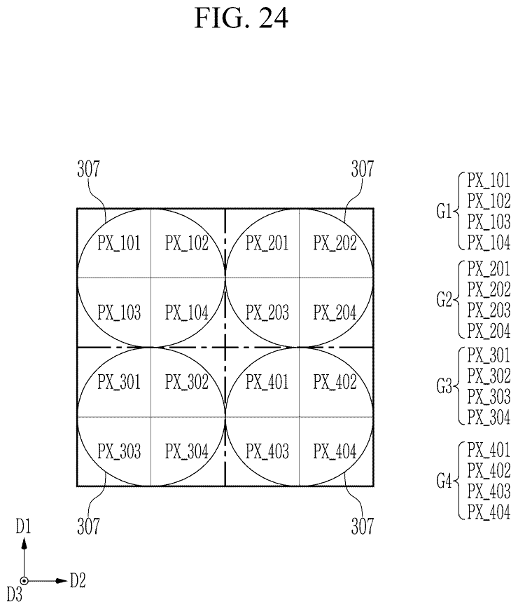

The first color filter 303R, the second color filter 303G, and the third color filter 303B may be arranged in a Bayer pattern. A specific arrangement of the first color filter 303R, second color filter 303G, and third color filter 303B will be described later with reference to FIG. 24 to FIG. 26.

As another example, the first color filter 303R, the second color filter 303G, and the third color filter 303B may include colors such as cyan, magenta, or yellow.

Referring to FIG. 5, shapes of the first color filter 303R, second color filter 303G, and third color filter 303B positioned in the red pixel PXR, green pixel PXG, and blue pixel PXB are different. As illustrated in FIG. 5, the third color filter 303B positioned in the blue pixel PXB may have a concave upper surface. That is, as illustrated in FIG. 5, the upper surface of the third color filter 303B may have a concave shape that is depressed in a direction of the first substrate 400. In this case, the upper surface of the third color filter 303B may form a curved surface with a certain curvature. This will be described separately later, but this is to solve a problem of the focus being formed at a different position for each pixel due to a difference in refractive index depending on a wavelength of light in the red pixel PXR, the green pixel PXG, and the blue pixel PXB

FIG. 5 illustrates an example case where the third color filter 303B of the blue pixel PXB has a concave shape, but according to an embodiment, upper surfaces of the first color filter 303R and the second color filter 303G may also have a concave shape. Specific modifications and effects will be described later.

Referring again to FIG. 5, an insulating structure 329 may be positioned between the second surface 400b of the first substrate 400 and the color filter 303. The insulating structure 329 may prevent reflection of light such that light incident on the second surface 400b of the first substrate 400 may smoothly reach the photoelectric conversion region 410. The insulating structure 329 may be referred to as an anti-reflection structure.

The insulating structure 329 includes a first fixed charge film 321, a second fixed charge film 323, and a planarization film 325 sequentially stacked on the second surface 400b of the first substrate 400.

The first fixed charge film 321, the second fixed charge film 323, and the planarization film 325 may include different materials. The first fixed charge film 321 may include any one of an aluminum oxide, a tantalum oxide, a titanium oxide, and a hafnium oxide. The second fixed charge film 323 may include any one of an aluminum oxide, a tantalum oxide, titanium oxide, and a hafnium oxide. For example, the first fixed charge film 321 may include an aluminum oxide, the second fixed charge film 323 may include a hafnium oxide, and the planarization film 325 may include a silicon oxide. Although not illustrated, in another embodiment, a silicon anti-reflection layer (not illustrated) may be interposed between the second fixed charge film 323 and the planarization film 325. The anti-reflection film may include a silicon nitride.

The microlens layer may be positioned on the color filter array 303. The microlenses 307 within the microlens layer may have a convex shape to focus light incident on the pixel PX. Each microlens 307 may vertically overlap the photoelectric conversion region 410. A shape of the lens may vary. In FIG. 5, one microlens 307 is illustrated to have a shape that overlaps one photoelectric conversion region 410, but one microlens 307 may overlap a plurality of photoelectric conversion regions 410. This will be described later in FIG. 24 to FIG. 26.

The light transmission layer 30 may further include a low refractive index pattern 311 and a protective film 316. The low refractive pattern 311 may be positioned between adjacent color filters 303 to separate them from each other. The low refractive pattern 311 may be positioned on the insulating structure 329. As an example, the low refractive pattern 311 may have a lattice structure. The low refractive pattern 311 may include a material with a lower refractive index than that of the color filter 303. The low refractive pattern 311 may include an organic material. For example, the low refractive pattern 311 may be a polymer layer including silica nanoparticles. The low refractive pattern 311 has a low refractive index, and thus an amount of light incident on the photoelectric conversion region 410 may be increased, and crosstalk between the pixels PX may be reduced. That is, light receiving efficiency may be increased in each photoelectric conversion region 410, and a signal noise ratio (SNR) characteristic may be improved.

The protective film 316 may cover a surface of the low-refractive pattern 311 with a substantially uniform thickness. The protective film 316 may include, e.g., a single film or a multi-film of at least one of an aluminum oxide film or a silicon carbide oxide film. The protective film 316 may protect the color filter 303, and may have a moisture absorption function.

The combination of the low refractive pattern 311 and the protective film 316 may constitute a color filter separation wall 317. The color filter separation wall 317 may be positioned between different color filters.

Referring again to FIG. 4, the image sensor according to an embodiment of the present disclosure may further include a logic chip 2000. The logic chip 2000 may be stacked on the sensor chip 1000. The logic chip 2000 may include a second substrate 500 and a second wiring region 40. The second wiring region 40 may be located between the first wiring region 20 and the second substrate 500.

In FIG. 4, the pixel array region AR may include a plurality of pixels PX. A description of the pixel array region AR is the same as previously described with reference to FIG. 2 to FIG. 5. Hereinafter, the optical black region OB and the pad region PAD will be described, mainly with reference to FIG. 4.

A first connection structure 50, a first pad terminal 81, and a bulk color filter 90 may be positioned on the first substrate 400 in the optical black region OB. The first connection structure 50 may include a first light blocking pattern 51, a first insulating pattern 53, and a first capping pattern 55. The first light blocking pattern 51 may be positioned on the second surface 400b of the first substrate 400. The first light blocking pattern 51 may uniformly cover inner walls of the third trench TR3 and the fourth trench TR4. The first light blocking pattern 51 may extend through the photoelectric conversion layer 10 and the first wiring region 20 to electrically connect the photoelectric conversion layer 10 and the first wiring region 20. More specifically, the first light blocking pattern 51 may contact a wire in the first wiring region 20 and the pixel separation pattern 450 in the photoelectric conversion layer 10. Accordingly, the first connection structure 50 may be electrically connected to wires in the first wiring region 20. The first light blocking pattern 51 may include a metal material, e.g., tungsten. The first light blocking pattern 51 may block light incident into the optical black region OB.

The first pad terminal 81 may be positioned inside the third trench TR3 to fill a remaining portion of the third trench TR3. The first pad terminal 81 may include a metal material, e.g., aluminum. The first pad terminal 81 may be connected to the pixel separation pattern 450.

The first insulating pattern 53 may be positioned the first light blocking pattern 51 to fill a remaining portion of the fourth trench TR4. The first insulating pattern 53 may extend through the photoelectric conversion layer 10 and the first wiring region 20. The first capping pattern 55 may be positioned on the first insulating pattern 53. The first capping pattern 55 may be positioned on the first insulating pattern 53.

The bulk color filter 90 may be positioned on the first pad terminal 81, the first light blocking pattern 51, and the first capping pattern 55. The bulk color filter 90 may cover the first pad terminal 81, the first light blocking pattern 51, and the first capping pattern 55. A first protective film 71 may be positioned on the bulk color filter 90 to cover the bulk color filter 90.

A photoelectric conversion area ‘10’ and a dummy region 411 may be positioned in the optical black region OB of the first substrate 400. For example, the photoelectric conversion region ‘10’ may be doped with impurities of a second conductivity type that is different from a first conductivity type. The second conductivity type may be, e.g., n-type. The photoelectric conversion region ‘10’ has a structure similar to that of the photoelectric conversion region 410 described in FIG. 5, but may not perform an operation of receiving light to generate an electrical signal. The dummy region 411 may be a region that is not doped with impurities. Signals generated in the photoelectric conversion region ‘10’ and the dummy region 411 may be used as information to remove a process noise later.

In the pad region PAD, a second connection structure 60, a second pad terminal 83, and a second protective film 73 may be positioned on the first substrate 400. The second connection structure 60 may include a second shading pattern 61, a second insulating pattern 63, and a second capping pattern 65.

The second light blocking pattern 61 may be positioned on the second surface 400b of the first substrate 400. More specifically, the second light blocking pattern 61 may uniformly cover inner walls of the fifth trench TR5 and the sixth trench TR6. The second light blocking pattern 61 may extend through portions of the photoelectric conversion layer 10, the first wiring region 20, and the second wiring region 40. More specifically, the second light blocking pattern 61 may contact the wires 231 and 232 in the second wire region 40. More specifically, the second light blocking pattern 61 may contact the wires 231 and 232 in the second wire region 40.

The second pad terminal 83 may be positioned inside the fifth trench TR5. The second pad terminal 83 may be positioned on the second light blocking pattern 61 to fill a remaining portion of the fifth trench TR5. The second pad terminal 83 may include a metal material, such as aluminum. The second pad terminal 83 may serve as an electrical connection path between the image sensor element and the outside. The second insulating pattern 63 may fill a remaining portion of the sixth trench TR6. The second insulating pattern 63 may fully or partially extend through the photoelectric conversion layer 10 and the first wiring region 20. The second capping pattern 65 may be positioned on the second insulating pattern 63. The second protective film 73 may cover a portion of the second light blocking pattern 61 and the second capping pattern 65.

A current applied through the second pad terminal 83 may flow to the pixel separation pattern 450 through the second light blocking pattern 61, the wires 231 and 232 in the second wiring region 40, and the first light blocking pattern 51. Electrical signals generated from the photoelectric conversion regions 410 and ‘10’ and the dummy region 411 may be transmitted to the outside through the wires in the first wiring region 20, the wires 231 and 232 in the second wiring region 40, the second light blocking pattern 61, and the second pad terminal 83.

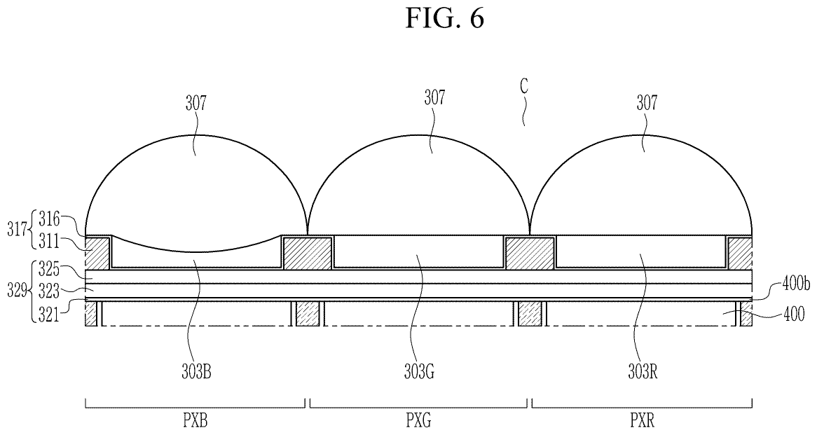

Hereinafter, a shape of the color filter, which is a main feature of the present disclosure, will be described with reference to FIG. 6.

FIG. 6 illustrates a separate view of a portion indicated by “C” in FIG. 5. Referring to FIG. 6, shapes of the first color filter 303R, the second color filter 303G, and the third color filter 303B are different. As illustrated in FIG. 5, the third color filter 303B positioned in the blue pixel PXB may have a concave upper surface. As an upper surface of the third color filter 303B has a concave shape, a problem of different focal lengths for each pixel including different color filters may be solved.

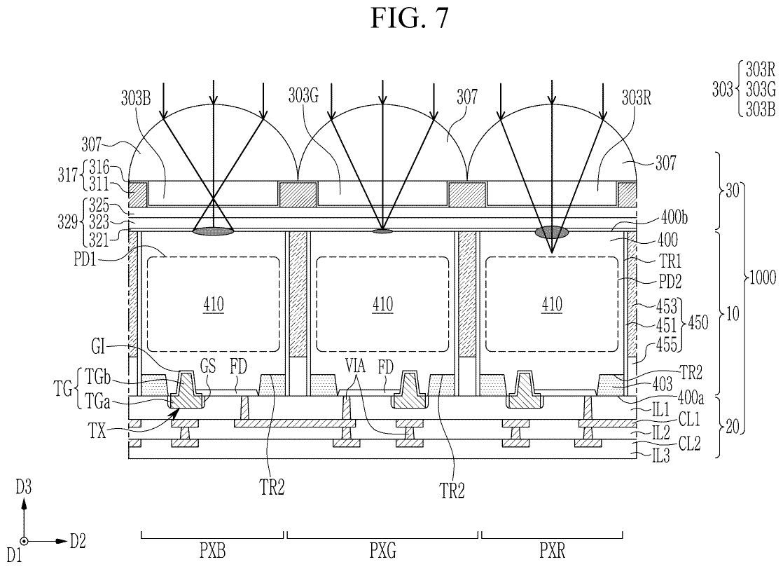

FIG. 7 illustrates a focus of light that is incident on an image sensor having a flat upper surface.

Referring to FIG. 7, it can be seen that focuses of the red pixel PXR, the green pixel PXG, and the blue pixel PXB are all different. This is because a refractive index of each wavelength of light is different. If light passes through media with different refractive indices, it is refracted at a boundary, and in this case, the refractive index varies depending on the wavelength of light. Accordingly, in FIG. 7, if light is incident on the color filter, a degree of refraction is different, and thus, a focus of the refracted light (i.e., focus) is focused on a different position for each pixel.

For an accurate operation of the image sensor, it may be desirable for the focus to be focused on an upper surface of the first substrate 400. As illustrated in FIG. 7, if the focus of the green pixel PXG is on the upper surface of the first substrate 400, the focus of the blue pixel PXB may be focused above the upper surface of the first substrate 400, and the focus of the red pixel PXR may be focused below the upper surface of the first substrate 400. This is due to the differences in refractive index depending on wavelengths.

However, in the image sensor according to the present embodiment, curvature of the color filter is formed differently for each pixel so that each pixel (i.e., refracted light corresponding to each pixel) is equally focused on the upper surface of the first substrate 400.

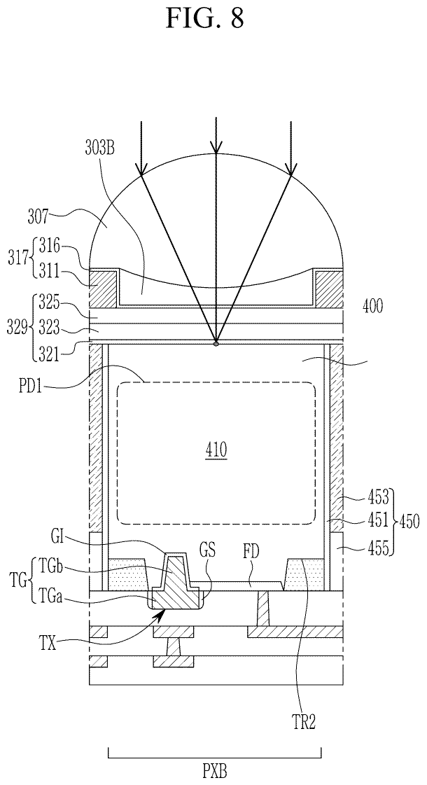

FIG. 8 illustrates incidence and a focus of light in the blue pixel PXB of FIG. 6. Referring to FIG. 8, light is refracted in a normal direction of an optical path by a concave upper surface of the third color filter 303B, and a focal distance increases. Accordingly, as illustrated in FIG. 8, as a path of light incident on the blue pixel PXB becomes longer, a focus moves downward and is focused on the upper surface of the first substrate 400. In this specification, the upper surface of the first substrate 400 may refer to the second surface 400b of the first substrate 400.

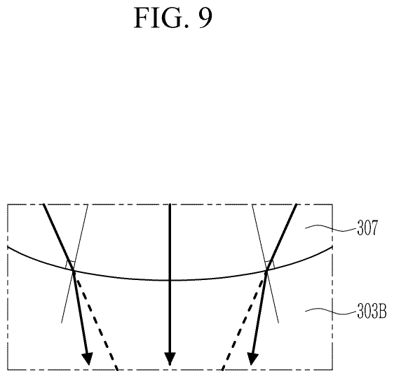

FIG. 9 illustrates an optical path between the third color filter 303B and an interface of a microlens. Referring to FIG. 9, an optical path in a case where an upper surface of the third color filter 303B is parallel is illustrated as a dotted line. Additionally, as illustrated in FIG. 9, an optical path in a case where the upper surface of the third color filter 303B is a concave curved surface is illustrated as a solid line. As illustrated in FIG. 9, if the upper surface of the third color filter 303B is a concave curved surface, it was confirmed that the optical path is refracted in the normal direction and the focal distance increases as the optical path becomes longer.

FIG. 6 illustrates an embodiment in which the upper surface of the third color filter 303B has a concave curved surface, but this is an example and the present disclosure is not limited thereto.

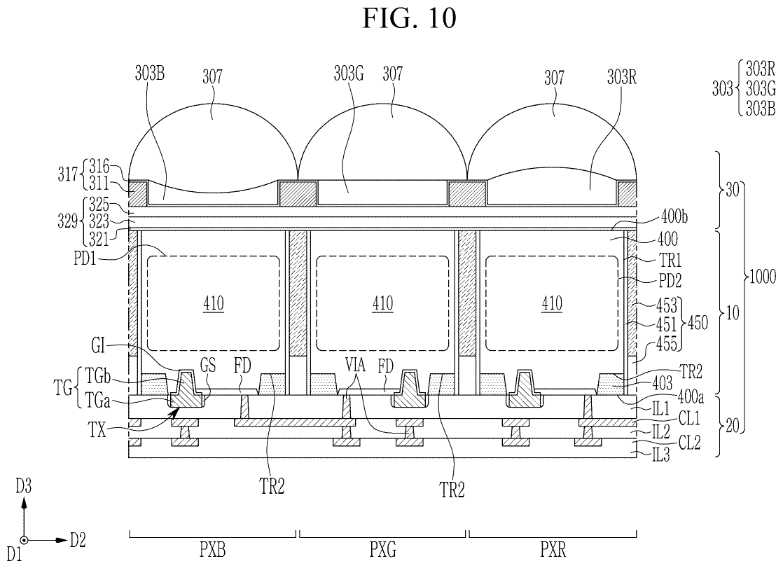

FIG. 10 illustrates a cross-section corresponding to that of FIG. 5 for another embodiment. Referring to FIG. 10, the image sensor according to the present embodiment is the same as the embodiment of FIG. 5 except that the upper surface of the first color filter 303R has a convex curved surface. A detailed description of same constituent elements will be omitted. Referring to FIG. 10, the upper surface of the first color filter 303R of the red pixel PXR has a convex curved surface. As previously illustrated in FIG. 7, a focus of the red pixel PX may be formed below the upper surface of the first substrate 400. In this case, if the optical path is shortened by making the upper surface of the first color filter 303R have a convex curve, as the focal distance becomes shorter, the focus may be focused on the upper surface of the first substrate 400.

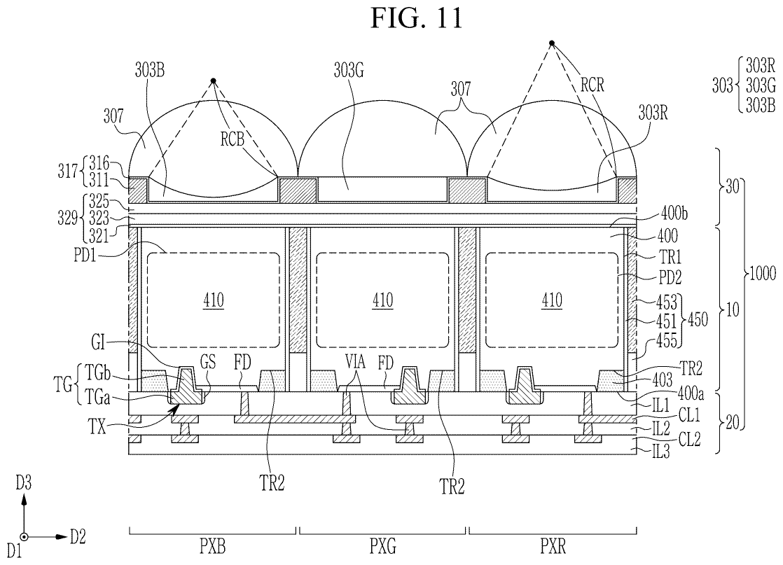

FIG. 11 illustrates a cross-section corresponding to that of FIG. 6 for another embodiment. Referring to FIG. 11, the image sensor according to the present embodiment is the same as the embodiment of FIG. 6 except that the upper surface of the first color filter 303R has a concave curved surface. A detailed description of same constituent elements will be omitted.

Referring to FIG. 11, a radius of curvature RCB of the upper surface of the third color filter 303B may be smaller than a radius of curvature RCR of the upper surface of the first color filter 303R. That is, curvature of the third color filter 303B may be greater than curvature of the first color filter 303R. As previously discussed, the optical path of light passing through the third color filter 303B is short, so this is to increase the optical path and move the focus downward. That is, as illustrated in FIG. 7, the optical path of the light passing through the third color filter 303B is the shortest and a distance between the focus and the upper surface of the first substrate 400 is the longest, and thus, the curvature of the third color filter 303B may be greater than that of other color filters.

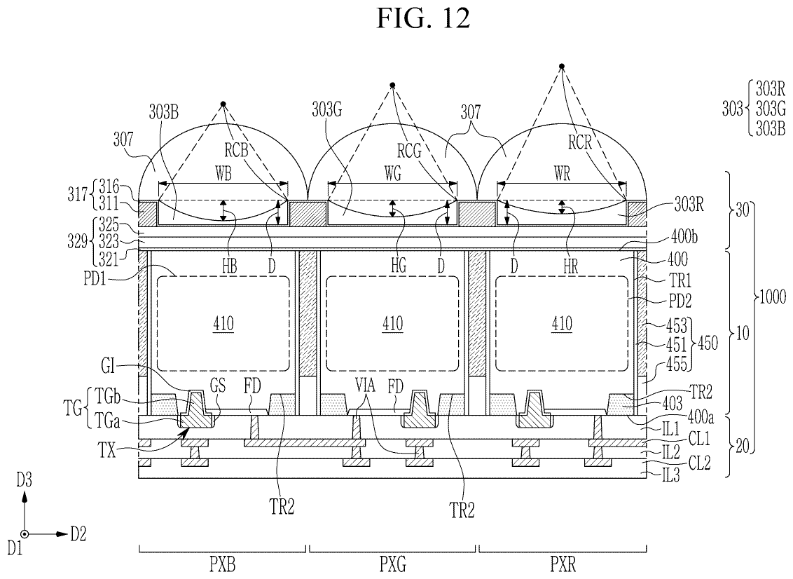

FIG. 12 illustrates a cross-section corresponding to that of FIG. 6 for another embodiment. Referring to FIG. 12, the image sensor according to the present embodiment is the same as the embodiment of FIG. 6 except that upper surfaces of the first color filter 303R, the second color filter 303G, and the third color filter 303B all have concave curved surfaces. A detailed description of same constituent elements will be omitted.

Referring to FIG. 12, a radius of curvature RCB of the third color filter 303B may be smaller than a radius of curvature RCG of the second color filter 303G. Additionally, a radius of curvature RCG of the second color filter 303G may be smaller than a radius of curvature RCR of the first color filter 303R. That is, the curvature of the third color filter 303B may be the largest, the curvature of the first color filter 303R may be the smallest, and the curvature of the second color filter 303G may be between the third color filter 303B and the first color filter 303R.

This is because, as reviewed previously, the degree to which light is refracted at the interface of the microlens and color filter varies depending on the wavelength. That is, blue light with the shortest wavelength is refracted the most and has a short optical path, and thus the third color filter 303B may have a highest curvature to correct this. Red light with a relatively long wavelength is refracted less than other lights and has a relatively long optical path, so the first color filter 303R may have a lower curvature compared to other color filters.

In the above, a degree of concavity of each color filter was described in terms of curvature, but the degree of concavity of a color filter may be determined in a way other than curvature.

Referring to FIG. 12, a degree of concavity of each color filter may be specified as a depth H of a concave portion relative to a width W of a color filter in the second direction D2=H/W. In FIG. 12, widths WR, WG, and WB of the first color filter 303R, the second color filter 303G, and the third color filter 303B, respectively, may be the same. However, this is only an example, and the widths WR, WG, and WB of the first color filter 303R, the second color filter 303G, and the third color filter 303B may be different. In addition, as illustrated in FIG. 12, depths HR, HG, and HB of most concave portions of the first color filter 303R, the second color filter 303G, and the third color filter 303B, respectively, are different. As illustrated in FIG. 12, the depth HB of the concave portion of the third color filter 303B may be the largest, the depth HG of the concave portion of the second color filter 303G may be the second largest, and the depth HR of the concave portion of the first color filter 303R may be the smallest. As will be described separately later, depending on a manufacturing method, a concave portion of each color filter may not have a smooth curved surface, and in this case, curvature may be replaced by the depth H of the concave portion=H/W for the width W of the color filter.

In FIG. 12, thicknesses D of the first color filter 303R, the second color filter 303G, and the third color filter 303B may be the same. However, this is only an example, and the present invention is not limited thereto. That is, depending on another embodiment, the thicknesses D of the first color filter 303R, the second color filter 303G, and the third color filter 303B may be different from each other.

The pixels illustrated in FIG. 6 to FIG. 12 may be a pixel positioned in a center of the pixel array region AR of the image sensor. In an embodiment, shapes of the color filters of the pixels positioned at an edge of the pixel array region AR and the pixels positioned at the center may be different.

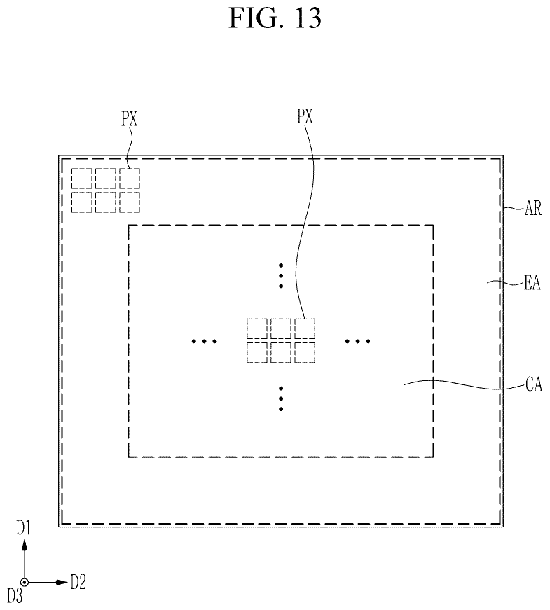

FIG. 13 briefly illustrates the pixel array region AR. In FIG. 13, a central area CA and an outer area EA are illustrated separately. As illustrated in FIG. 13, the outer area EA may be positioned to surround the central area CA. The pixels of FIG. 6 to FIG. 12 described above may be pixels positioned in the central area CA, and pixels positioned in the outer area EA will be described below.

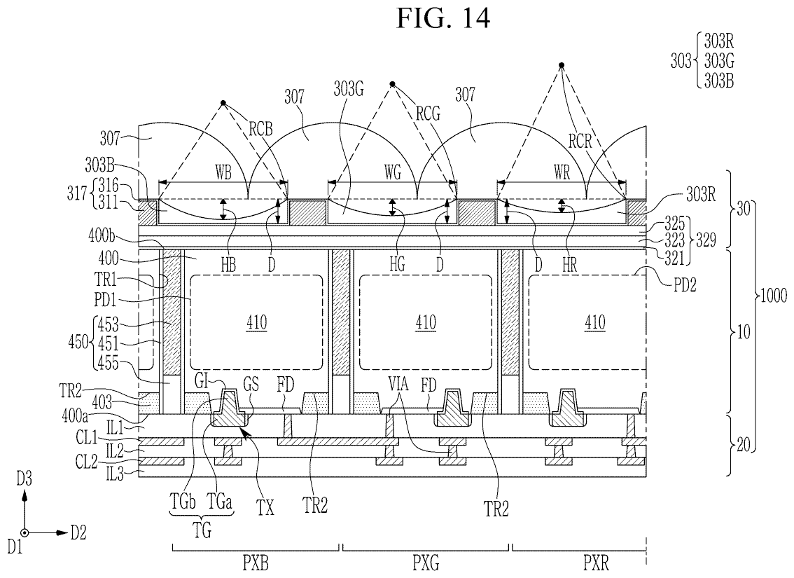

FIG. 14 illustrates an area corresponding to that of FIG. 5 for a pixel positioned in the outer area EA. Referring to FIG. 14, the image sensor according to the present embodiment is the same as the embodiment of FIG. 5 except for the shape of the microlens 307 and the disposition of each color filter 303. A detailed description of same constituent elements will be omitted.

Referring to FIG. 14, a center of each microlens is positioned to be offset from a center of each pixel. That is, a thickest portion of the microlens does not match a central portion of the color filter. This is to correct light coming in at an oblique angle from an outside of the image sensor so that the light coming in at the oblique angle may be positioned at the center of each pixel.

Additionally, as illustrated in FIG. 14, in the outer area EA, the color filter separation wall 317 and the pixel separation pattern 450 may be positioned so as not to overlap each other. That is, the light transmission layer 30 and the photoelectric conversion layer 10 may be shifted and positioned, and as described earlier, since light enters at an oblique angle on the outside of the image sensor, this is to correct the light entering at the oblique angle to be positioned in the center of each pixel. In FIG. 14, the color filter separation wall 317 and the pixel separation pattern 450 are illustrated not overlapping, but this is merely an example, and in another embodiment, the color filter separation wall 317 and a portion of the pixel separation pattern 450 may be positioned to overlap each other. Alternatively, the light transmission layer 30 and the photoelectric conversion layer 10 may be positioned further shifted than illustrated in FIG. 14. This may vary appropriately depending on a position of the pixel.

As such, in the outer area EA, the center of the microlens 307, the center of the color filter 303, and the center of the photoelectric conversion region 410 do not coincide with each other (i.e., do not overlap in the vertical direction), and since the center of the pixel and the center of the corresponding microlens are positioned at an offset, the focus of a pixel positioned in the outer area EA may be different from the focus of a pixel positioned in the central area CA.

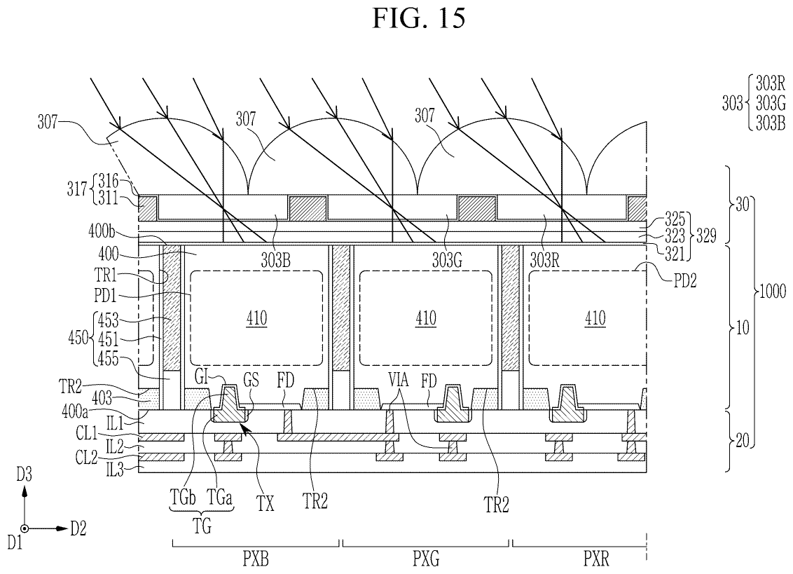

FIG. 15 illustrates a focus of a pixel positioned in the outer area EA. FIG. 15 simply illustrates only some components for convenience of description. Referring to FIG. 15, it can be seen that due to the misalignment of the microlens and the pixel, focuses of the blue pixel PXB and the green pixel PXG are focused above the upper surface of the first substrate 400 rather than on the upper surface.

However, in the image sensor according to the present embodiment, an upper surface of each color filter is concave to increase the optical path and the focus is moved downward to focus on the upper surface of the first substrate 400.

Referring again to FIG. 14, upper surfaces of the first color filter 303R, the second color filter 303G, and the third color filter 303B have a concave shape. In this case, a radius of curvature RCB of the third color filter 303B may be smaller than a radius of curvature RCG of the second color filter 303G. Additionally, a radius of curvature RCG of the second color filter 303G may be smaller than a radius of curvature RCR of the first color filter 303R. That is, the curvature of the third color filter 303B may be the largest, the curvature of the first color filter 303R may be the smallest, and the curvature of the second color filter 303G may be between the third color filter 303B and the first color filter 303R.

This is because, as reviewed previously, the degree to which light is refracted at the interface of the microlens and color filter varies depending on the wavelength. That is, blue light with the shortest wavelength is refracted the most and has a short optical path, and thus the third color filter 303B may have a highest curvature to correct this. Red light with a relatively long wavelength is refracted less than other lights and has a relatively long optical path, so the first color filter 303R may have a lower curvature compared to other color filters.

Additionally, in FIG. 14, the depth H of the concave portion=H/W relative to the width W of the color filter may be the largest for the third color filter 303B. In FIG. 14, widths WR, WG, and WB of the first color filter 303R, the second color filter 303G, and the third color filter 303B, respectively, may be the same. As illustrated in FIG. 14, depths HR, HG, and HB of most concave portions of the first color filter 303R, the second color filter 303G, and the third color filter 303B, respectively, are different. As illustrated in FIG. 12, the depth HB of the concave portion of the third color filter 303B may be the largest, the depth HG of the concave portion of the second color filter 303G may be the second largest, and the depth HR of the concave portion of the first color filter 303R may be the smallest. Accordingly, the depth H of the concave portion relative to the width W of the color filter (=H/W) may be the largest for the third color filter 303B, the second color filter 303G may be the next largest, and the first color filter 303R may be the smallest.

As the upper surfaces of the first color filter 303R, the second color filter 303G, and the third color filter 303B have a concave shape, an optical path of the light incident on each pixel may be increased and the focus may be moved downward so that it is focused on the upper surface of the first substrate 400.

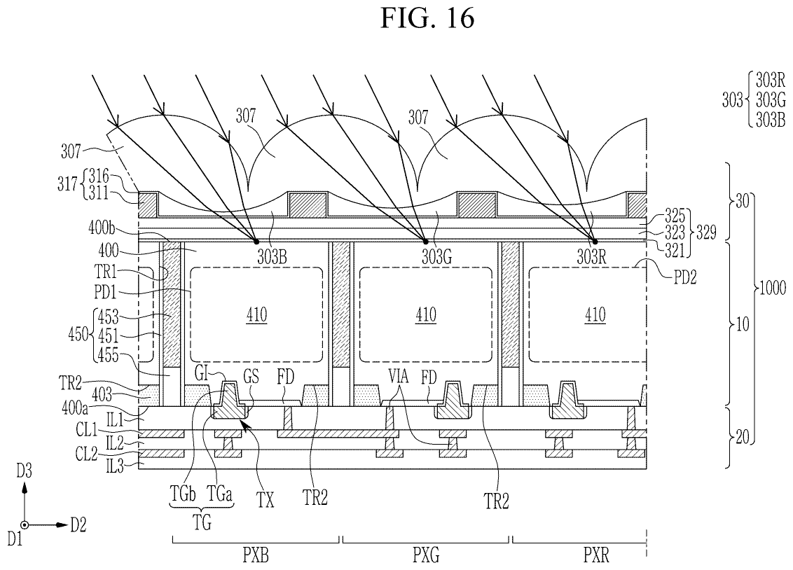

FIG. 16 illustrates a focus of a pixel positioned in the outer area EA of an image sensor according to an embodiment. Referring to FIG. 16, light is refracted in a normal direction of an optical path by a concave upper surface of the color filters 303G and 303B, and a focal distance increases. Accordingly, as illustrated in FIG. 16, as a path of incident light becomes longer, a focus moves downward and is focused on the upper surface of the first substrate 400.

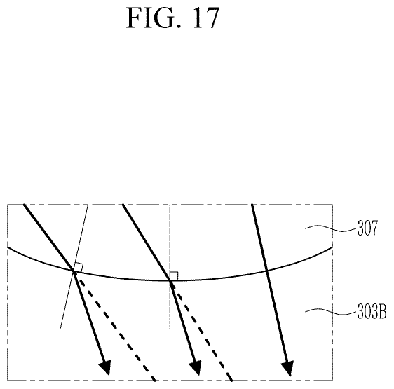

FIG. 17 illustrates an optical path at an interface between the third color filter 303B and the microlens 307 of the image sensor positioned in the outer area EA. Referring to FIG. 17, an optical path in a case where an upper surface of the third color filter 303B is parallel is illustrated as a dotted line. Additionally, as illustrated in FIG. 17, an optical path in a case where the upper surface of the third color filter 303B is a concave curved surface is illustrated as a solid line. Referring to FIG. 9, if the upper surface of the third color filter 303B is a concave curved surface, it was confirmed that the optical path is refracted in the normal direction and the focal distance increases as the optical path becomes longer.

In this case, curvature of the upper surface of the color filter may be different for the pixels positioned in the outer area EA and the pixels positioned in the central area CA even if they are pixels of the same color. That is, for pixels of a same color, curvature of a pixel positioned in the outer area EA may be greater than curvature of a pixel positioned in the central area CA. This is because, as illustrated in FIG. 15, for the pixel positioned in the outer area EA, a degree of focus deviation from the upper surface of the first substrate 400 is greater due to the misalignment of the microlens and the pixel. That is, comparing FIG. 7 with FIG. 15, in order to focus on the upper surface of the first substrate 400, a distance to move is greater in the outer area EA than in the central area CA, and thus the curvature of the color filter positioned in the outer area EA may be greater than the curvature of the color filter positioned in the central area CA.

As such, the image sensor according to the present embodiment may compensate for focus shift due to misalignment between the microlens 307 and the pixel region by forming a concave portion on the upper surface of the color filter, and thus a degree of misalignment between the microlens 307 and the pixel region may be reduced. That is, generally, in order to form a focus at the center of the pixel region in the outer area EA, a center of the microlens 307 and a center of the pixel region are positioned at a certain distance. However, in the present embodiment, a focus position is adjusted by forming a concave portion on the upper surface of the color filter, and thus a degree to which the microlens 307 and the pixel region are misaligned may be minimized. That is, for example, in the case of an image sensor including a color filter with a flat upper surface, when applying a chief ray angle (CRA) of 35°, a distance between a center of the microlens and a center of the pixel region was 0.64 μm. However, when forming a concave portion on the upper surface of the color filter as in the present embodiment, the distance between the center of the microlens and the center of the pixel region decreased to 0.54 μm if the CRA of 35° was applied. In other words, it was confirmed that the degree of misalignment between the microlens and the pixel region could be reduced by about 15.6%.

In FIG. 14, a configuration in which upper surfaces of the first color filter 303R, the second color filter 303G, and the third color filter 303B are all concave is shown, but this is merely an example, and at least one of the first color filter 303R, the second color filter 303G, or the third color filter 303B may have a concave shape, and the others may have a flat upper surface or a convex upper surface.

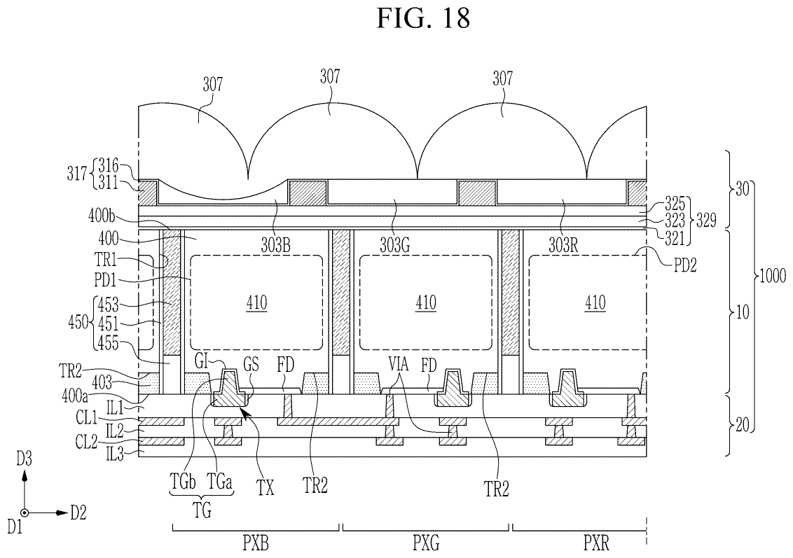

FIG. 18 illustrates a cross-section corresponding to that of FIG. 14 for another embodiment. That is, as illustrated in FIG. 18, in the outer area EA, the upper surface of the third color filter 303B may have a concave shape, and the upper surfaces of the second color filter 303G and the first color filter 303R may be flat.

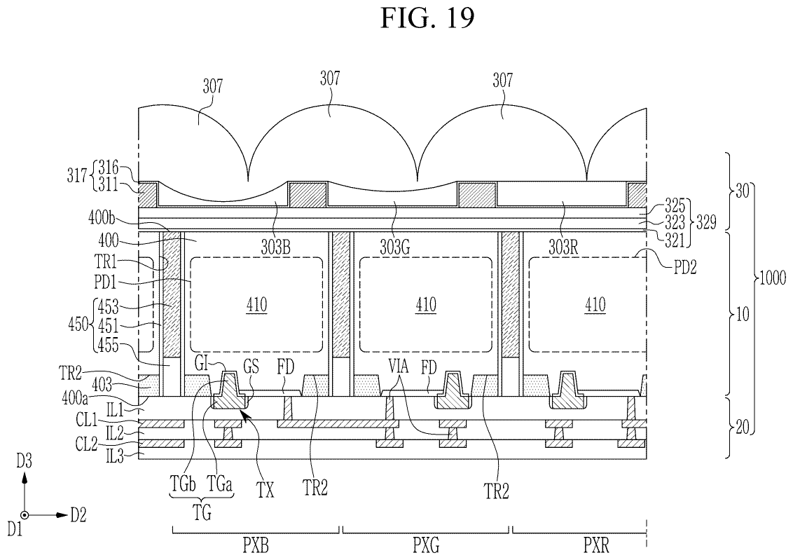

FIG. 19 illustrates a cross-section corresponding to that of FIG. 14 for another embodiment. As illustrated in FIG. 19, in the outer area EA, the upper surfaces of the third color filter 303B and the second color filter 303G may have a concave shape, and the upper surface of the first color filter 303R may have a flat shape. Although not illustrated in a separate drawing, various other combinations are included in the present disclosure.

Additionally, the color filter positioned in the outer area EA may include a concave portion and a convex portion together, or may include a concave portion and a flat portion.

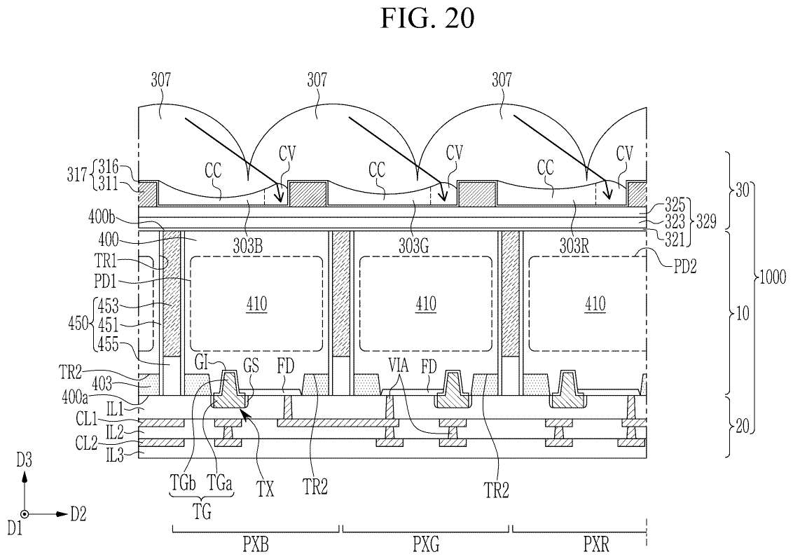

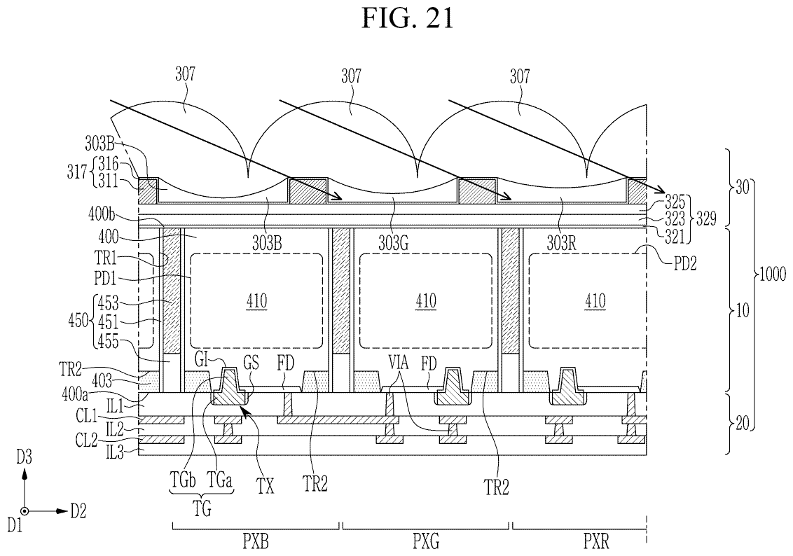

FIG. 20 illustrates a cross-section corresponding to that of FIG. 14 for another embodiment. Referring to FIG. 20, in the image sensor according to the present embodiment, one or more of the first color filter 303R, the second color filter 303G, and the third color filter 303B may include a concave portion CC and a convex portion CV. As illustrated in FIG. 21, since the center of the microlens 307 and the center of the pixel region are misaligned at the outside, an edge portion of the color filter 303 may block a path of incident light. FIG. 21 illustrates a configuration in which an edge portion of the color filter 303 blocks a path of incident light. As illustrated in FIG. 21, incident light may enter neighboring pixels through the edge portion where a concave portion is formed. However, as illustrated in FIG. 20, if the edge portion of the third color filter 303 is formed to be convex to lower a height of the edge portion of the color filter 303, it may not block a path of light coming in at an angle.

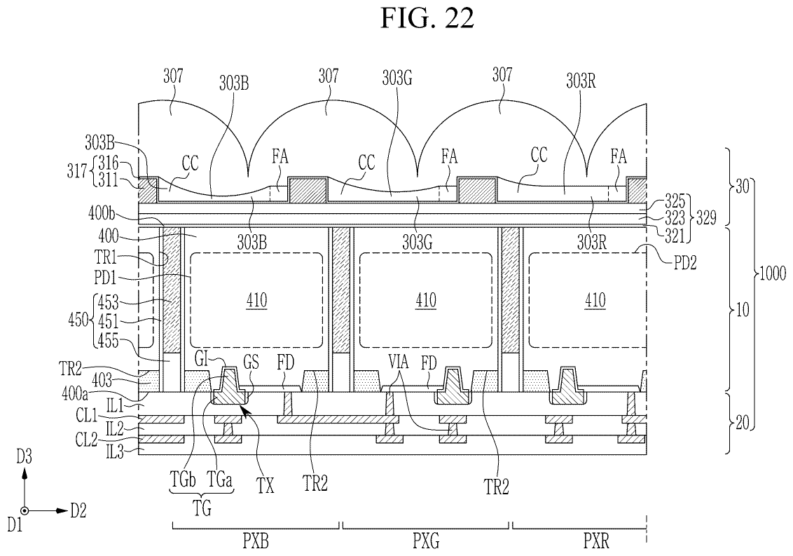

FIG. 22 illustrates a cross-section corresponding to that of FIG. 20 for another embodiment. Referring to FIG. 22, the image sensor according to the present embodiment is the same as that of the embodiment of FIG. 20 except that it includes a flat portion FA instead of a convex portion. A detailed description of same constituent elements will be omitted. Referring to FIG. 22, in the image sensor according to the present embodiment, one or more of the first color filter 303R, the second color filter 303G, and the third color filter 303B may include a concave portion CC and a flat portion FA. As illustrated in FIG. 22, since a thickness of the color filter 303 becomes thin in the flat portion FA, it may not block a path of light entering diagonally toward neighboring pixels.

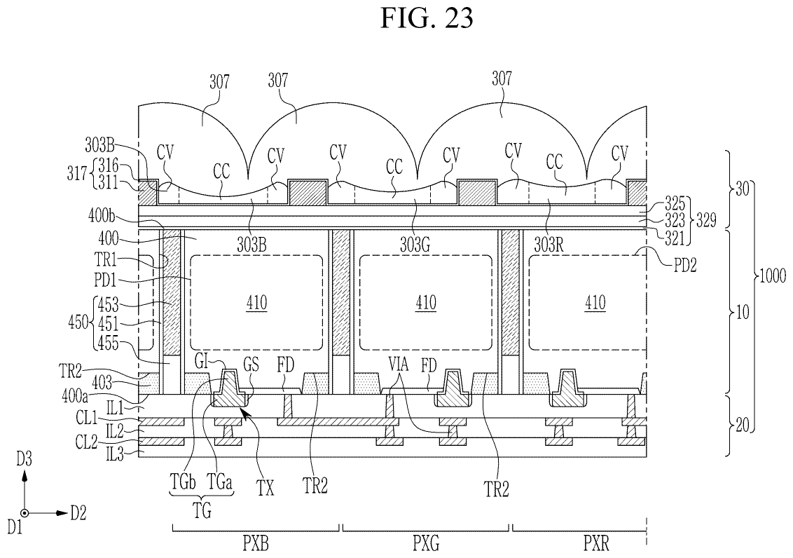

FIG. 23 illustrates a cross-section corresponding to that of FIG. 20 for another embodiment. Referring to FIG. 23, the image sensor according to the present embodiment is the same as that of the embodiment of FIG. 20 except that convex portions CV are positioned at opposite sides of the concave portion CC of the color filter. A detailed description of same constituent elements will be omitted.

As such, the image sensor according to the present embodiment ensures that an upper surface of at least one of the first color filter 303R, the second color filter 303G, or the third color filter 303B in the central area CA and the outer area EA has a concave curved surface, to position a focus on the upper surface of the first substrate 400. Accordingly, performance of the image sensor was improved.

Effects of the image sensor according to the present embodiment will be described in detail below with reference to Table 1. In Table 1 below, Comparative Example 1 indicates an image sensor in which upper surfaces of the first color filter 303R, the second color filter 303G, and the third color filter 303B are all flat, and Example 1 indicates an image sensor in which at least one of the first color filter 303R, the second color filter 303G, or the third color filter 303B has a concave curved upper surface.

TABLE 1

| | | Comparative Example 1 | Example 1 |
|---|---|---|---|
| Sensitivity | Blue | 100 | 107.2 |
| | Green | 100 | 100.6 |
| | Red | 100 | 106.7 |
| AFC | Center (CRA 0°) | 100 | 100.5 |
| | Edge (CRA 35°) | 100 | 112 |

In Table 1, relative performance of Example 1 is shown by setting performance of Comparative Example 1 to 100.

Referring to Table 1 above, it was confirmed that the image sensor according to Example 1 had increased sensitivity to each color. That is, if the color filter includes a concave curved surface as in this embodiment, it was confirmed that the focus of the pixel including each color filter could be focused on the upper surface of the first substrate 400, and that sensitivity to each color increased.

In addition, it was confirmed that an auto focus contrast (AFC) in the central area and the outer area (CRA) 36° also increased. In particular, it was confirmed that the AFC in the outer area was significantly improved.

In the above, for convenience of description, a configuration in which one microlens corresponds to one photoelectric conversion region is illustrated, but a number of photoelectric conversion regions corresponding to one microlens may vary according to an embodiment.

FIG. 24 illustrates a top plan view describing a structure in which one microlens is formed every 2*2 pixels,

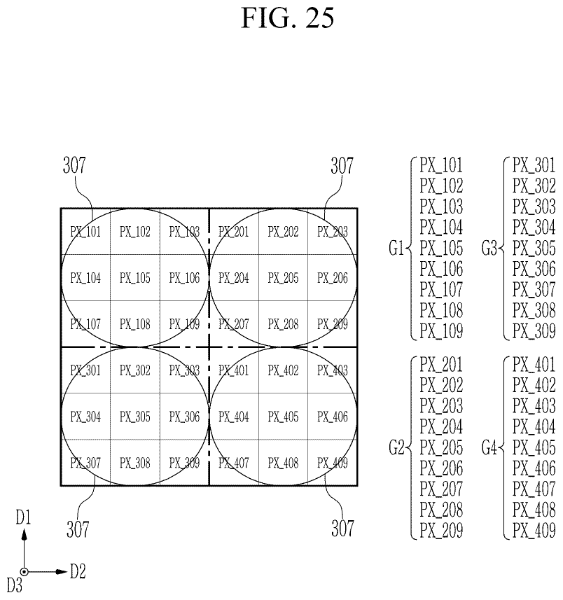

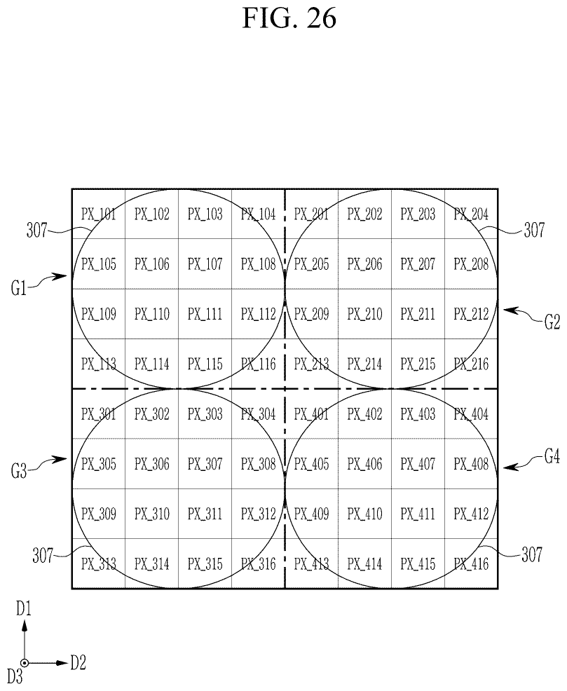

FIG. 25 illustrates a top plan view describing a structure in which one microlens is formed every 3*3 pixels, and FIG. 26 illustrates a top plan view describing a structure in which one microlens is formed every 4*4 pixels.

Referring to FIG. 24, four sub-pixel groups G1, G2, G3, and G4 are illustrated. The first sub-pixel group G1 may include first to fourth unit pixels PX_101, PX_102, PX_103, and PX_104. The second sub-pixel group G2 may include first to fourth unit pixels PX_201, PX_202, PX_203, and PX_204. The third sub-pixel group G3 may include first to fourth unit pixels PX_301, PX_302, PX_303, and PX_304. The fourth sub-pixel group G4 may include first to fourth unit pixels PX_401, PX_402, PX_403, and PX_404. Each of the first sub-pixel group G1, the second sub-pixel group G2, the third sub-pixel group G3, and the fourth sub-pixel group G4 may overlap one microlens 307. The first color filter 303R may be positioned to overlap the first sub-pixel group G1, the second color filter 303G may be positioned to overlap the second sub-pixel group G2 and the third sub-pixel group G3, and the third color filter 303B may be positioned to overlap the fourth sub-pixel group G4. However, this is an example and disposition of the color filters may vary. The first color filter 303R, the second color filter 303G, and the third color filter 303B may have the shape described above.

FIG. 25 is the same as FIG. 24 except that each of the sub-pixel group G1, G2, G3, and G4 includes 9 unit pixels. A detailed description of same constituent elements will be omitted. As in FIG. 25, the first color filter 303R may be positioned to overlap the first sub-pixel group G1, the second color filter 303G may be positioned to overlap the second sub-pixel group G2 and the third sub-pixel group G3, and the third color filter 303B may be positioned to overlap the fourth sub-pixel group G4. However, this is an example and disposition of the color filters may vary. The first color filter 303R, the second color filter 303G, and the third color filter 303B may have the shape described above.

FIG. 26 is the same as FIG. 24 except that each of the sub-pixel group G1, G2, G3, and G4 includes 16 unit pixels. A detailed description of same constituent elements will be omitted.

Hereinafter, various methods for manufacturing a color filter according to the present embodiment will be described.

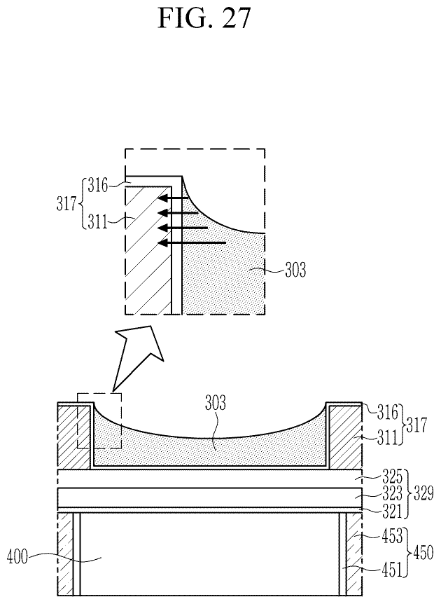

FIG. 27 illustrates a manufacturing method for a color filter according to an embodiment. Referring to FIG. 27, viscosity of a color filter material may be improved to form a curved surface by surface tension. That is, the color filter with improved viscosity may have a shape as shown in FIG. 27 due to surface tension with a side surface of the protective film 316. In other words, a height of an edge portion of the color filter 303 may be higher due to surface tension with the side surface of the protective film 316. In FIG. 27, this surface tension is shown by an arrow. In this case, a concave upper surface of the color filter 303 may be naturally formed.

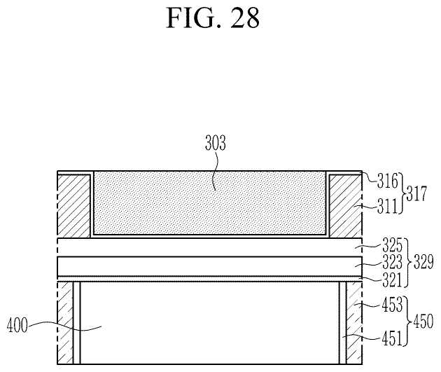

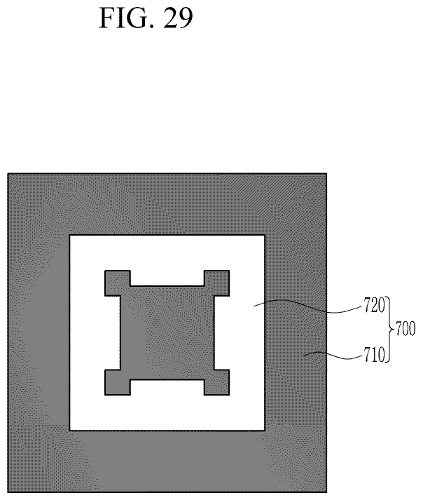

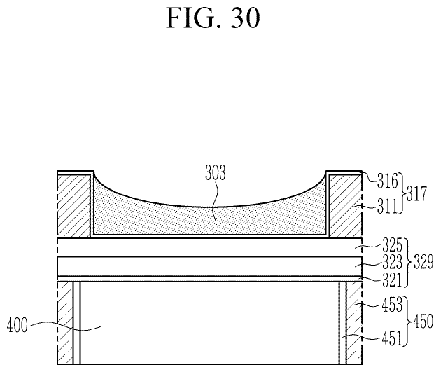

FIG. 28 to FIG. 30 illustrate a manufacturing method for a color filter according to another embodiment. Referring to FIG. 28, the color filter 303 is formed. Next, the color filter 303 is exposed and developed using a mask 700 having an opening 720 and a light blocking portion 710 as illustrated in FIG. 29. In this case, a color filter 303 having a shape illustrated in FIG. 30 may be manufactured due to an energy difference between an exposed portion and an unexposed portion.

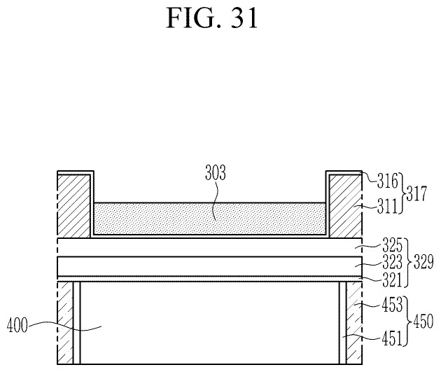

FIG. 31 to FIG. 36 illustrate a manufacturing method for a color filter 303 according to another embodiment. An embodiment illustrated in FIG. 31 to FIG. 36 shows a method of forming a concave curved surface by repeating deposition of the color filter 303 two or more times.

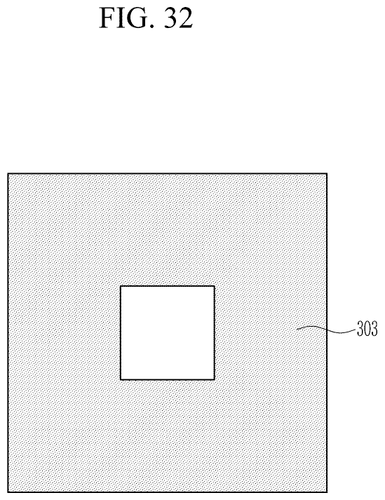

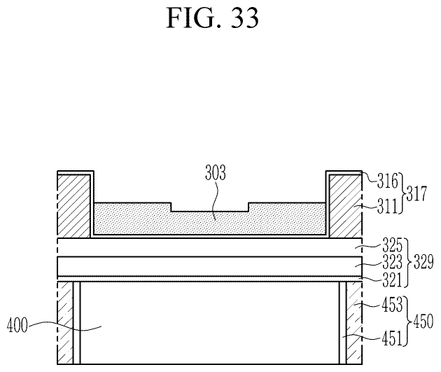

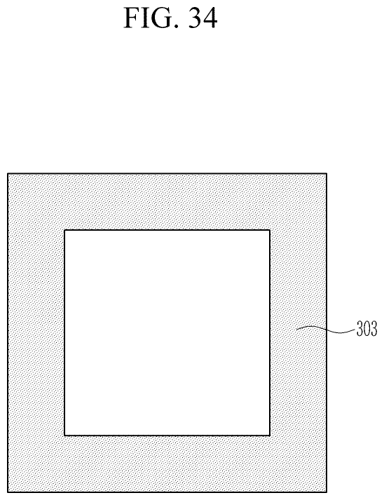

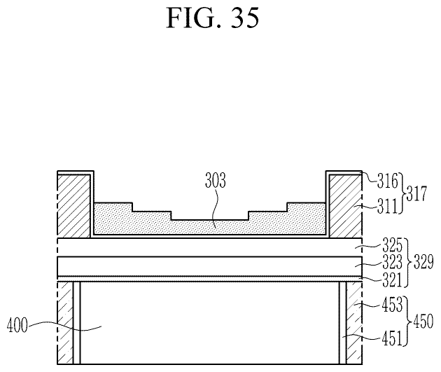

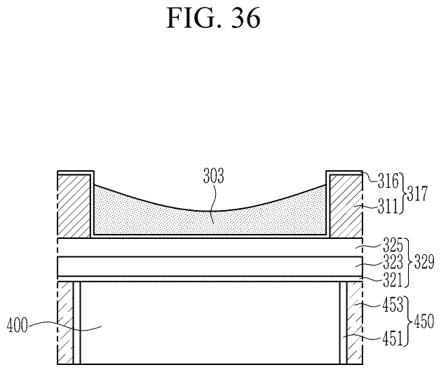

Referring to FIG. 31, a color filter 303 is first formed. Next, a color filter 303 is formed in a planar shape as illustrated in FIG. 32. In this case, a color filter 303 having a cross-sectional shape as illustrated in FIG. 33 may be formed. Next, in a case of forming a color filter 303 in a planar shape as illustrated in FIG. 34, a color filter 303 having a cross-sectional shape as illustrated in FIG. 35 may be formed. In FIG. 33 and FIG. 35, the color filter 303 is illustrated as having a step in a cross-sectional view to distinguish areas of the color filter deposited at each stage, but an actual shape may have a concave curved surface as illustrated in FIG. 36. This is because when the color filter 303 is deposited at each stage, a natural curved surface is formed as the color filter 303 flows to neighboring portions.

However, the manufacturing method described above is merely an example, and the present disclosure is not limited thereto.

As described above, the image sensor and the manufacturing method therefor according to the present embodiment may optimize the optical path and improve the optical characteristic by ensuring that the upper surface of at least one color filter has a concave curved surface. Specifically, a problem of different focus positions of pixels including color filters of different colors was solved, and the distance between the microlens and the pixel region at the outer edge was minimized.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. An image sensor comprising:
a substrate including first and second surfaces facing each other and a plurality of photoelectric conversion regions;
a plurality of color filters positioned on the second surface of the substrate, the plurality of color filters including a first color filter, a second color filter, and a third color filter; and
a microlens layer including a plurality of microlenses and positioned to overlap each of the color filters,
wherein an upper surface of at least one of the first color filter, the second color filter, or the third color filter has a concave curved surface, and
wherein a curvature of the upper surface of the third color filter is different from a curvature of the upper surface of the second color filter or a curvature of the upper surface of the first color filter.

2. The image sensor of claim 1, wherein
the first color filter is a red color filter,
the second color filter is a green color filter,
the third color filter is a blue color filter, and
the upper surface of the third color filter has a concave curved surface.

3. The image sensor of claim 2, wherein
the upper surface of the first color filter has a convex curved surface.

4. The image sensor of claim 2, wherein
the upper surface of the first color filter has a concave curved surface.

5. The image sensor of claim 4, wherein
the upper surface of the second color filter has a concave curved surface.

6. The image sensor of claim 2, wherein
the curvature of the upper surface of the third color filter is greater than curvature of the upper surface of the first color filter.

7. The image sensor of claim 6, wherein
the curvature of the upper surface of the third color filter is greater than the curvature of the upper surface of the second color filter, and
curvature of the upper surface of the second color filter is greater than curvature of the upper surface of the first color filter.

8. The image sensor of claim 1, wherein
the substrate includes a central region and an outer region positioned to surround the central region, and
a center of each of the color filters and a center of each of the microlenses do not overlap in a vertical direction in the outer region.

9. The image sensor of claim 8, wherein
the curvature of the upper surface of the third color filter positioned in the outer region is greater than the curvature of the upper surface of the third color filter positioned in the central area.

10. The image sensor of claim 8, wherein
a color filter positioned in the outer region of the image sensor includes a concave portion and a convex portion.

11. The image sensor of claim 10, wherein
the concave portion is positioned between convex portions.

12. The image sensor of claim 1, wherein
each of the first color filter, the second color filter, and the third color filter is positioned to overlap a plurality of photoelectric conversion regions.

13. The image sensor of claim 1, wherein
the microlens layer is positioned to overlap each of the first color filter, the second color filter, and the third color filter.

14. An image sensor comprising:
a substrate including first and second surfaces facing each other and a plurality of photoelectric conversion regions;
a plurality of color filters positioned on the second surface of the substrate, the plurality of color filters including a red color filter, a green color filter, and a blue color filter; and
a microlens layer including a plurality of microlenses and positioned to overlap each of the color filters,
wherein an upper surface of at least one of the red color filter, the green color filter, or the blue color filter includes a concave portion, and
wherein a ratio of a depth of a most concave portion of the blue color filter to a width of the blue color filter is different from a ratio of a depth of a most concave portion of the red color filter to a width of the red color filter or a ratio of a depth of a most concave portion of the green color filter to a width of the green color filter.

15. The image sensor of claim 14, wherein
the depth of the most concave portion of the blue color filter is deeper than the most concave portion of the green color filter.

16. The image sensor of claim 14, wherein
the depth of the most concave portion of the green color filter is deeper than the concave portion of the green color filter.

17. An image sensor comprising:
a substrate including first and second surfaces facing each other and a plurality of photoelectric conversion regions;
a plurality of color filters positioned on the second surface of the substrate, the plurality of color filters including a first color filter, a second color filter, and a third color filter; and
a microlens layer including a plurality of microlenses and positioned to overlap each of the color filters,
wherein the substrate includes a central region and an outer region positioned to surround the central region,
wherein an upper surface of the third color filter has a concave curved surface, and
wherein a curvature of the upper surface of the third color filter positioned in the outer region is greater than the curvature of the upper surface of the third color filter positioned in the central region.

18. The image sensor of claim 17, wherein
the first color filter is a red color filter,
the second color filter is a green color filter,
the third color filter is a blue color filter, and
an upper surface of the second color filter has a concave curved surface, and
a curvature of the upper surface of the second color filter positioned in the outer region is greater than a curvature of the upper surface of the second color filter positioned in the central region.

19. The image sensor of claim 18, wherein
an upper surface of the first color filter has a concave curved surface, and
a curvature of the upper surface of the first color filter positioned in the outer region is greater than a curvature of the upper surface of the first color filter positioned in the central region.

20. The image sensor of claim 17, wherein
the color filter positioned in the outer area of the image sensor includes a concave portion and a convex portion.
